(19) United States
(12) Patent Application Publication
(10) Pub. No.: US 2026/0329170 A1
(43) Pub. Date: Oct. 22, 2026

(54) MANUFACTURING OF OPTICAL DEVICES USING NANOPARTICLE DISPERSIONS

(71) Applicants: University of Massachusetts, Westborough, MA (US); Myrias Optics, Inc., Amherst, MA (US)

(72) Inventors: James Watkins, South Hadley, MA (US); Vincent J. Einck, Palmer, MA (US); Daeeon Jung, Westborough, MA (US); Amir Arbabi, Westfield, MA (US)

(21) Appl. No.: 19/653,476

(22) Filed: Apr. 21, 2026

Related U.S. Application Data
(60) Provisional application No. 63/792,750, filed on Apr. 22, 2025.

(51) Int. Cl. G03F 7/00

(52) U.S. Cl. CPC G03F 7/0002; G03F 7/0005

(57) ABSTRACT

Techniques are directed to formulating an imprinting composition that includes at least a first nanoparticle having a first size and a second nanoparticle having a second size different from the first size. By blending two or more different-sized particles, and optionally different-sized binders, the composition significantly increases the particle packing density within the imprinted structures. This additive manufacturing approach directly patterns optical features where the height is greater than the width, specifically enabling high aspect ratio (AR) nanostructures greater than 10:1, 15:1, or even 20:1.

### CROSS REFERENCE TO RELATED APPLICATIONS

This application claims the benefit of U.S. Provisional Application No. 63/792,750, filed on Apr. 22, 2025, the disclosure of which is hereby incorporated by reference in its entirety.

This invention was made with government support under CMMI1025020, and 2122654 awarded by the National Science Foundation. The government has certain rights in the invention.

### BACKGROUND

Some manufacturing schemes for optical devices have been based on subtractive manufacturing using platforms and tools common to the semiconductor industry, e.g., optical lithography.

### SUMMARY

The concepts discussed herein are directed to high efficiency optical devices containing patterned nanofeatures and microfeatures operating in the UV, visible and IR wavelengths and methods for their manufacturing based on nanoparticles. Patterned nanoparticle structures may be formed by additive manufacturing techniques such as nanoimprint lithography. Specific techniques demonstrated herein have aspect ratios greater than 10:1, high refractive indices, and large patternable feature sizes to fabricate optical devices and components including metalenses, collimators, beam shapers, collimating beam splitters, waveguides, lightwave circuits, optical switches, couplers, and other optical parts. The high aspect ratio structures can be achieved through the formulation of nanoparticle-based dispersions comprising of mixtures of different sized particles, which can increase particle packing density, and can reduce feature shrinkage and related cracking behavior of thick films and large structures. Post-processes including calcination, atomic layer deposition (ALD), and high temperature annealing process can enable the fine tuning of refractive index, annealed particle size, surface roughness, and feature dimension. An additional refractive index boost by ALD can provide a further degree of increase, and combined, the increased packing from the nanoparticle blends and the refractive index increase from ALD can provide the highest refractive index to date for these direct nanoimprint lithography processable materials at 2.30 at 543 nm. Methods to control and suppress the surface roughness and grain size of the patterned structures reduce light scattering and power loss during light propagation, restricting grain size coarsening to at least 1/20 of the wavelength through modifications of binder structures, ligand structures, or material selections of atomic layer deposition which can suppress excessive merging and coarsening of nanoparticles during thermal annealing.

In a general aspect, an optical device can include a substrate. The optical device can also include a layer disposed on the substrate. The layer can include a composition that includes a first nanoparticle having a first size. The layer can also include a composition that includes a second nanoparticle having a second size different from the first size. The layer can further include at least one feature on a surface of the layer opposite the substrate, the at least one feature being formed from the composition and having a height greater than a width of the at least one feature.

In another general aspect, a method can include forming a composition. The composition can include a first nanoparticle having a first size, and a second nanoparticle having a second size different from the first size. The method can also include forming a layer on a substrate by depositing the composition on the substrate. The method can further include forming at least one feature on a surface of the layer opposite the substrate, the at least one feature having a height greater than a width of the at least one feature.

The details of one or more implementations are set forth in the accompanying drawings and the description below. Other features will be apparent from the description and drawings, and from the claims.

### BRIEF DESCRIPTION OF THE DRAWINGS

FIG. 1 is a diagram illustrating an example direct patterning process of nanoparticle-based dispersions based on nanoimprint lithography, according to the implementations described herein.

FIG. 2 is a diagram illustrating an example schematic description of increasing particle density by adding different sized particles.

FIG. 3 is a diagram illustrating an example schematic description of the effects of particle size distributions on the viscosity of the particle dispersion and the filling mechanism through narrow channels in a stamp.

FIG. 4 is a diagram illustrating an example plot of refractive index and film shrinkage of as-cured and calcined films at varying blending ratios of 10 nm and 20 nm TiO2 nanoparticles.

FIG. 5 is a diagram illustrating example top-down scanning electron microscope (SEM) images of nanopillars fabricated with TiO2 dispersions, demonstrating reduced crack formation by mixing different sized particles.

FIG. 6 is a diagram illustrating an example schematic description showing the effects of the device design on the imprintability of high aspect ratio features based on pattern density.

FIG. 7 is a diagram illustrating an example schematic description comparing the effects of the hard PDMS (hPDMS) layer thickness on the fabrication of high aspect ratio features.

FIG. 8 is a diagram illustrating an example schematic description showing the effects of a two-step curing process on feature shrinkage to enable an easier release of the stamp.

FIG. 9 is a diagram illustrating example nanostructures fabricated by direct NIL with an aspect ratio greater than 10.

FIG. 10 is a diagram illustrating example nanostructures fabricated by direct NIL with an aspect ratio greater than 15 and a height greater than 1 μm.

FIG. 11 is a diagram illustrating example nanostructures fabricated by direct NIL with an aspect ratio greater than 20 and a height greater than 2 μm.

FIG. 12 is a diagram illustrating example metalenses operating in visible wavelengths with absolute efficiencies exceeding 80% and relative efficiencies exceeding 90%.

FIG. 13 is a diagram illustrating an example chart of absolute efficiencies of metalenses processed with different methods of organic removal after imprinting.

FIG. 14 is a diagram illustrating an example plot of FTIR graphs of the planar films processed through different methods to verify the removal of residual organics.

FIG. 15 is a diagram illustrating an example achievement of a high refractive index up to 2.3 utilizing two particle sizes combined with calcination and ALD.

FIG. 16 is a diagram illustrating an example schematic description showing the effects of blending two different-sized particles on the accessible pores for the atomic layer deposition process.

FIG. 17 is a diagram illustrating example SEM images of metalens structures where a sacrificial NOA binder induces porosity during calcination.

FIG. 18 is a diagram illustrating example plots of the refractive index, film thickness, and film shrinkage of planar films utilizing a metal-oxo cluster (TiOC) as an inorganic binder at varying concentrations.

FIG. 19 is a diagram illustrating example cross-sectional SEM images of as-imprinted binary grating patterns using varying concentrations of a metal-oxo cluster (TiOC) as an inorganic binder.

FIG. 20 is a diagram illustrating example plots of the film properties of planar films prepared using the metal-oxo cluster (TiOC) to partially replace TiO2 nanoparticles.

FIG. 21 is a diagram illustrating example cross-sectional SEM images of as-imprinted binary grating patterns where TiO2 nanoparticles are replaced by TiOC at different weight ratios.

FIG. 22 is a diagram illustrating example plots of the refractive index demonstrating RI tunability by using different nanoparticles backfilled with different ALD precursors.

FIG. 23 is a diagram illustrating example SEM images of directly printed metalens structures prepared using BaTiO3, ZrO2, and HfO2 nanoparticle-based inks.

FIG. 24 is a diagram illustrating example plots of the UV-vis spectra of ZrO2 and HfO2 nanoparticle-based films, showcasing their high transmittance in UV wavelength regimes.

FIG. 25 is a diagram illustrating an example schematic description showing directly printed metasurface-based collimating beam splitters targeting thousands of dots when combined with a VCSEL array.

FIG. 26 is a diagram illustrating an example display of split dots on a dark screen at a distance of 30 cm utilizing a collimating beam splitter combined with a VCSEL array.

FIG. 27 is a diagram illustrating an example full screen image of a collimating beam splitter combined with a VCSEL array showing dot counts of approximately 15,000 for a wider field of view.

FIGS. 28A and 28B are diagrams illustrating example cross-sectional and top-down SEM images of line patterns fabricated with TiO2 nanoparticle-based dispersions.

FIG. 29 is a diagram illustrating example cross-sectional SEM images of patterned line structures calcined at 450 °C in air.

FIG. 30 is a diagram illustrating example cross-sectional SEM images of patterned line structures calcined at 1000 °C in air to show increased surface roughness.

FIG. 31 is a diagram illustrating an example schematic description showing a process of pore filling between particles utilizing atomic layer deposition.

FIG. 32 is a diagram illustrating example plots of the refractive index of TiO2 nanoparticle-based films in terms of ALD cycles and wavelength-dependent RI changes after full ALD backfilling.

FIG. 33 is a diagram illustrating an example schematic description showing the suppressing effects of binders on crystal phase transformation and grain size coarsening.

FIG. 34 is a diagram illustrating an example schematic description showing structural suppressing effects of binders via steric hindrance.

FIG. 35 is a diagram illustrating an example schematic description showing the suppressing effects of specialized ligands on crystal phase transformation and grain size coarsening.

FIG. 36 is a diagram illustrating an example schematic description showing the suppressing effects of core-shell particles on crystal phase transformation.

FIG. 37 is a diagram illustrating an example schematic description showing the suppressing effects of thin ALD layers placed between particles.

FIG. 38 is a diagram illustrating an example schematic description showing the effects of thermal cycling rates during rapid thermal annealing processes.

FIG. 39 is a diagram illustrating example top-down SEM images of line patterns comparing the effects of different binder types during the thermal annealing process.

FIG. 40 is a diagram illustrating example cross-sectional SEM images of line patterns comparing the effects of a silane coupling agent versus a polymeric binder after thermal annealing.

FIG. 41 is a diagram illustrating example cross-sectional SEM images of high aspect ratio nanopillars comparing the effects of binder types and the thermal annealing process.

FIG. 42 is a diagram illustrating example wide-angle x-ray plots comparing planar films fabricated with a silane coupling agent and a polymeric binder across annealing temperatures.

FIG. 43 is a diagram illustrating example plots of the refractive index and film thickness variations in relation to the binder concentration comparing two different binder types.

FIG. 44 is a diagram illustrating example plots of the wavelength-dependent refractive index curves comparing two different binder types before and after full ALD backfilling.

FIG. 45 is a diagram illustrating an example plot of the wavelength-dependent refractive index of a TiO2 film utilizing a polymeric binder that is fully backfilled by TiO2 ALD.

FIG. 46 is a diagram illustrating an example schematic description showing an ALD cladding process utilized to smoothen the surface roughness and fill in thermal cracks.

FIG. 47 is a flow chart illustrating a method of performing a manufacture of optical devices according to the improved techniques described herein.

### DETAILED DESCRIPTION

The technology described herein enables creating advanced optical devices such as diffractive optical elements (DOEs), metalenses, flat-top beam shapers, collimating beam splitters, waveguides, and lightwave circuits. Conventional approaches to manufacturing such advanced optical devices have relied on subtractivbe manufacturing. These conventional methods utilize platforms and tools common to the semiconductor industry. Nevertheless, such subtractive manufacturing schemes may be time-consuming and expensive, and the precise etching used for these advanced optical structures may be difficult to achieve across a broad selection of materials. To overcome these subtractive manufacturing limitations and seek more fast, scalable, and cost-effective fabrication, additive manufacturing approaches were explored, including direct patterning based on nanoimprint lithography (NIL).

In conventional additive manufacturing approaches utilizing NIL, the primary materials used include nanoparticle (NP) dispersions. Such NP dispersions may include NP/binder composites, which in turn may include nanoparticles combined with polymer binders, organic binders, inorganic binders, or precursors to inorganic binders. These formulations may rely on monodisperse spherical particles, which may limit the packing density of the resulting structures. Additionally, the pre-polymers or polymers acting as binders to hold the nanoparticles together may be viscous, restricting the flow and moldability of the dispersion.

A technical problem with the use of these conventional NP/binder composites is that such conventional materials may present severe limitations regarding the optical properties of the fabricated devices. Devices prepared through imprinting these composites may fail to achieve high absolute efficiencies greater than 75%. This inefficiency may be tied to the fabrication limits of the NIL-based patterning, specifically the inability to achieve both a high refractive index (RI) and a high aspect ratio (AR). With these conventional materials, as-imprinted structures were restricted to RIs of no more than 2.0 and ARs of no more than 10. In practice, typical aspect ratios rarely exceeded 8.5, with known examples achieving ARs of only 5.0, 8.3, 8.4, and 8.5. While thermal annealing may be used to phase-transform particles to increase the RI, this process can cause excessive grain size coarsening and surface roughness, scattering light and limiting practical applications.

Beyond optical limitations, the conventional materials can cause significant physical and mechanical issues during the spin-coating and curing stages of fabrication. It can be difficult to produce films thick enough to completely and uniformly fill tall nanostructures using the spin-coating-based process. Achieving sufficient film thickness while maintaining sufficient fluidity may be particularly problematic at high nanoparticle loadings. Furthermore, monodisperse nanoparticle formulations may suffer from severe dimensional shrinkage and residual stress. This can lead to cracking of the thick films during UV or thermal curing and post-processing, which may restrict the heights of high aspect ratio features to no more than one micron.

A technical solution to the technical problem addresses the limitations of conventional monodisperse nanoparticle dispersions by formulating an imprinting composition that includes at least a first nanoparticle having a first size and a second nanoparticle having a second size different from the first size. By blending two or more different-sized particles, and optionally different-sized binders, the composition significantly increases the particle packing density within the imprinted structures. This additive manufacturing approach directly patterns optical features where the height is greater than the width, specifically enabling high aspect ratio (AR) nanostructures greater than 10:1, 15:1, or even 20:1.

A technical advantage of the technical solution is the dramatic improvement in the rheological and mechanical properties of the dispersion during fabrication. Blending different-sized nanoparticles lowers the viscosity of the suspension at high solid loadings, utilizing a phenomenon known as the Farris Effect. This lower viscosity facilitates capillary action, allowing the dispersion to quickly and completely fill the narrow channels of high AR master stamps. Furthermore, the denser particle packing achieved during the spin-coating and imprinting stages minimizes dimensional shrinkage and residual stress during subsequent curing and calcination. The reduced shrinkage suppresses crack formation, which conventionally restricted film heights, thus allowing the reliable fabrication of structural features greater than 1, 1.5, or even 2 microns in height without excessive breakage during the stamp demolding process.

Optically, the technical solution's multi-sized nanoparticle formulation overcomes previous refractive index (RI) ceilings. The tighter packing of blended nanoparticles inherently produces a higher initial RI and optical density than monodisperse systems. This performance is further enhanced through post-imprint atomic layer deposition (ALD), which uniformly backfills the remaining nanoscale pores between the densely packed particles with high-index metal oxides such as TiO₂, ZrO₂, or HfO₂. The combination of particle blending and ALD backfilling can boost the RI of the resulting structures to 2.30 or higher. By simultaneously achieving high RIs and extremely high ARs, the resulting optical devices—such as metalenses, diffractive optical elements, and collimating beam splitters—can achieve Fresnel-corrected absolute efficiencies exceeding 80% in visible wavelengths and 70% in infrared wavelengths, while providing high numerical apertures.

Also, the technical solution addresses the grain size coarsening and surface roughening typically caused by high-temperature thermal annealing. Instead of standard highly viscous organic polymers, the formulation can incorporate specific inorganic binders—such as silane coupling agents leaving SiO₂ linkages, metal-oxo clusters, or caged polymers—that physically separate the nanoparticles and suppress direct contact during phase transformations to denser crystalline structures. Along with optional ALD cladding layers that can smoothen the final surface and fill any thermal cracks, this careful control of the composition prevents excessive particle merging. As a result, the root-mean-square surface roughness can be kept to less than 1/20 of the target wavelength, preventing excessive light scattering and enabling high-efficiency waveguide performance with losses below 0.2 dB/cm.

Using the disclosed techniques, the above-described technology can be used in the fabrication of high-efficiency metalenses, which are designed to diffract light to a single focal point. This enhanced NA allows for a decreased focal length, which significantly reduces the required spacing between elements within a lens tube, making optical assemblies more compact and increasing resolution for applications like microscopy. Furthermore, the invention enables the creation of asymmetric pillar shapes that interact with different light polarizations separately. This unique polarization sensitivity allows metalenses to selectively focus or splay specific polarizations without the severe optical data loss typical of traditional wire grid polarizers, making them highly valuable for advanced imaging and sensing devices.

Another example involves the production of collimating beam splitters and holographic projecting elements. Unlike lenses that focus light, these elements splay or spread light to targeted points across an area larger than the device itself. The ability of the technical solution to significantly increase the refractive index of the materials provides a much greater field of view (FOV) for these components. In practice, metasurface-based collimating beam splitters patterned with this technology can be combined with vertical-cavity surface-emitting laser (VCSEL) arrays to create highly effective dot projectors for facial recognition, machine vision, and terrain mapping. Through nanoparticle blending and post-imprint atomic layer deposition, these beam splitters can project tens of thousands of individual dots across wide fields of view (e.g., 75 by 83 degrees) while achieving average absolute dot efficiencies up to 70%.

Another example is the creation of low-loss waveguides and planar lightwave circuits. Waveguiding structures require the efficient propagation of light and rely heavily on total internal reflection to prevent the loss of in-coupled light. The exceptionally high refractive indices achieved by the invention's nanoparticle mixtures directly fulfill the requirements for total internal reflection across visible and infrared wavelengths. Moreover, power loss in waveguides is often caused by light scattering from rough surfaces. Because the technical solution utilizes specialized inorganic binders, optimized ligands, and atomic layer deposition cladding layers to prevent excessive grain size coarsening and fill in thermal cracks, it ensures an extremely smooth structural surface. By keeping the surface roughness strictly below 1/20 of the target wavelength, these devices prevent excess light scattering, enabling pristine waveguide performance with optical losses as low as 0.2 dB/cm.

As used herein, the term “substrate” refers to a foundational base or underlying material upon which a layer, such as a nanoparticle and binder composition, is deposited, spin-coated, or otherwise formed to create an optical device. The substrate provides structural support and must be carefully selected to manage physical properties, such as the adhesion strength at the imprint-substrate interface, to prevent delamination during the demolding process. Furthermore, to prevent cracking during high-temperature post-processing, it is important to minimize mismatches in the thermal expansion coefficients between the substrate material and the imprinted structures. In some practical optical device designs, the backside of the substrate may also include an anti-reflection coating to improve performance. Specific examples of substrates can include glass (such as high-index glass), silicon (Si), fused silica, and flexible materials like PET (polyethylene terephthalate) sheets, which can also be used as a backing substrate for patterned stamps. Substrates may also encompass other standard optical and semiconductor materials such as quartz, sapphire, polycarbonate, or other specialized rigid and flexible polymer wafers.

As used herein, the term “layer” refers to a thickness or expanse of material disposed or formed upon a supporting surface, such as an underlying substrate. In the context of the above-described optical devices, a layer is formed by depositing a specially formulated composition onto the substrate, which can be accomplished through techniques such as spin-coating. This layer composition includes a densified blend of building blocks, such as a first nanoparticle and a second nanoparticle having different sizes, and may additionally include various binders. The layer acts as the foundational physical medium from which optical geometries are produced; specifically, it can be patterned to include at least one nanostructured or microstructured feature on the surface of the layer opposite the substrate. Furthermore, the patterned layer is often designed to be substantially optically transparent in response to at least one wavelength of incident light. To provide a broader technical context common in the field, a layer generally refers to any discrete thin film, coating, or stratum laid over a surface that provides specific structural, optical, or protective functionalities within a microfabricated device assembly.

As used herein, the term “composition” refers to a formulation or mixture of distinct chemical and physical ingredients combined to create an imprintable material, such as a dispersion or ink. In the context of the described technology, the composition essentially encompasses a plurality of nanoparticles, specifically including at least a first nanoparticle having a first size and a second nanoparticle having a second size different from the first size. To increase the particle packing volume and adjust structural properties, the composition incorporates a plurality of binders, which can also include a first binder and a second binder having different sizes. Additionally, the composition can be diluted by incorporating one or more low boiling point solvents or high boiling point solvents to control its fluidity. This blended material is deposited onto a substrate to form a layer, which is then manipulated—typically using a patterned mold via nanoimprint lithography—to form patterned nanostructured or microstructured features. Such a composition may also denote the qualitative and quantitative makeup of any chemical mixture, solution, or composite material tailored to exhibit specific physical, chemical, or rheological properties.

As used herein, the term “nanoparticle” refers to a nanoscale physical particle that acts as a fundamental solid building block within an imprintable composition or dispersion. the context of the described optical devices, a plurality of nanoparticles are utilized—specifically blending at least a first nanoparticle having a first size and a second nanoparticle having a second size (such as 10 nm and 20 nm)—to maximize packing density, minimize physical shrinkage, and enhance the final refractive index of fabricated high-aspect-ratio optical features. These nanoparticles are primarily composed of inorganic materials, especially high-index metal oxides, and specific examples include titanium dioxide (TiO₂), zirconium dioxide (ZrO₂), hafnium dioxide (HfO₂), niobium pentoxide (Nb₂O₅), barium titanate (BaTiO₃), tungsten disulfide (WS₂), aluminum oxide (Al₂O₃), silicon dioxide (SiO₂), silicon carbide (SiC), or various mixtures and core-shell combinations thereof. Additionally, these nanoparticles possess one or more crystalline phases that can undergo thermally induced phase transformations to denser crystalline structures. According to the described formulations, the nanoparticles generally maintain an average particle size of less than 100 nm, and specific subsets may possess mean diameters of less than 50 nm, less than 20 nm, less than 10 nm, or even less than 5 nm. A nanoparticle may be generally defined as a discrete particle of matter with all three spatial dimensions ranging between 1 and 100 nanometers, which often exhibits unique optical, chemical, and physical behaviors compared to its bulk counterpart due to an exceptionally high surface-area-to-volume ratio.

As used herein, the term “feature” refers to a distinct nanostructure or microstructure patterned on the surface of a layer opposite an underlying substrate. These features are formed from a deposited composition comprising a densified blend of nanoparticles and binders. A feature is characterized by its physical dimensions and geometry, frequently possessing a height that is substantially greater than its width. Specifically, the technical solution references the fabrication of high-aspect-ratio features, where the ratio of the feature's height to its width or diameter can readily exceed 10:1, 15:1, 20:1, or even 25:1. The critical dimensions of these features can span from the nanoscale (e.g., greater than 50 nm) up to microscale sizes (e.g., up to 10 microns). In optical device designs, a feature can take various structural forms, including nanopillars, straight line patterns, slanted gratings, curved lines, or two-dimensional networks. Furthermore, a feature may be engineered to have an asymmetric shape—meaning it has different widths in two orthogonal directions—which allows the structure to selectively interact with and control different polarizations of light. A feature may denote any intentionally patterned three-dimensional geometry, topographic element, or functional component created during microfabrication to impart specific structural, optical, or electrical properties to a given device architecture.

As used herein, the term “surface” refers to the outermost boundary, exterior face, or superficial area of a material, layer, or structural component. In the specific context of the described optical devices, the term frequently denotes the top boundary of the deposited composition layer—specifically the “surface of the layer opposite the substrate”—upon which nanostructured or microstructured features are directly formed using nanoimprint lithography. The term is also used throughout the specification to describe the interactive interfaces of other processing components, such as the functional exterior face of a patterned stamp applied to the layer, the chemically modified boundary of a stamp treated to control adhesion, or the physical exterior of the resulting optical structures themselves, whose “surface roughness” must be carefully controlled to minimize optical scattering. A surface describes the continuous two-dimensional boundary dividing two distinct physical phases (such as a solid-gas or solid-liquid interface) where critical chemical and physical interactions, such as adhesion, surface energy, and capillary action, take place.

As used herein, the terms “height” and “width” refer to the primary physical dimensions that define the spatial geometry of a patterned nanostructure or microstructure, such as a pillar or grating line. Specifically, the “height” designates the vertical elevation or perpendicular distance of the feature measured from its base at the supporting layer's surface to its uppermost peak. In the described advanced optical devices, the physical height of these nanofeatures can be strategically increased to enhance overall optical efficiency, and can readily exceed dimensions of 1 micron, 1.5 microns, or even 2 microns. Conversely, the “width” refers to the lateral or horizontal extent of the feature measured across its transverse axis. In meta-optics designs, fabricating narrow widths provides the necessary gradient in phase delay to precisely diffract light. Furthermore, specific features may be designed asymmetrically to have different widths in two orthogonal directions, enabling the structures to selectively interact with and control different polarizations of light. Together, the mathematical relationship between these two critical dimensions dictates the structural “aspect ratio,” which is calculated by dividing the feature's height by its width or diameter. The described additive manufacturing technology inherently focuses on producing features where the height is substantially greater than the width, particularly enabling high-aspect-ratio geometries where the height is at least ten times larger than the width (a ratio of 10:1 or greater).

As used herein, the term “binder” refers to a material or substance used to hold, connect, or draw other building blocks, such as nanoparticles, together within a composition to form a cohesive structural whole. Binders are incorporated into nanoparticle dispersion inks to make the patterned nanostructures mechanically stronger, allowing them to withstand stamp release forces during nanoimprinting and enabling the successful fabrication of complex, high-aspect-ratio features. Binders can perform several diverse structural roles: they can reinforce the resulting device through the formation of chemical bonds or linkages between the primary nanoparticles; they can act as sacrificial or removable materials (such as certain organic polymers) that are intentionally burned out to induce porosity for subsequent atomic layer deposition backfilling; or they can act as physical barriers (such as caged polymers, metal-oxo clusters, or silane coupling agents) that sterically separate nanoparticles to suppress excessive grain size coarsening and surface roughening during high-temperature phase transformations. To increase the particle packing volume and adjust rheological properties, formulations may blend a first binder and a second binder having different sizes, with individual binder diameters potentially being less than 1 nm, 3 nm, or 5 nm. Specific examples of binder materials include, but are not limited to, polymers, monomers, alkoxides, oligomers, prepolymers, transparent optical adhesives, silanes, metal oxides or metal oxide precursors, sol-gel materials, cross-linkable materials, Si-containing polymers, branched polymers, and silsesquioxanes.

As used herein, the term “size” refers to the physical dimensions or spatial extent of a discrete building block, such as a nanoparticle or a binder, within an imprintable composition. In the context of the described optical devices, the term is frequently characterized by a particle's diameter or mean diameter. For instance, the described technology references blending a first nanoparticle having a first size and a second nanoparticle having a second size different from the first size (such as discrete particles having average sizes or mean diameters of 10 nm and 20 nm) to maximize the overall particle packing density, reduce structural shrinkage, and lower the viscosity of the dispersion. The plurality of nanoparticles generally possesses an average particle size of less than 100 nm, while specific nanoparticle or binder subsets within the formulation may be restricted to sizes less than 50 nm, 20 nm, 10 nm, 5 nm, 3 nm, or even 1 nm in diameter. The size of a nanoscale particle typically denotes its equivalent spherical diameter, primary crystallite size, or hydrodynamic diameter, which is generally measured and verified using standard analytical techniques such as scanning electron microscopy (SEM), transmission electron microscopy (TEM), or dynamic light scattering (DLS).

As used herein, the terms “polymer,” “monomer,” “alkoxide,” “oligomer,” “prepolymer,” “insulating material,” “transparent optical adhesive,” “silane,” “metal oxide,” “metal oxide precursor,” “sol-gel material,” “cross-linkable material,” “Si-containing polymer,” “caged polymer,” “branched polymer,” “silane coupling agent,” “silsesquioxane,” and “metal-oxo cluster” generally refer to various classes of materials that can be incorporated into an imprintable formulation, primarily functioning as binders or structural additives to hold nanoparticles together, modulate rheology, or control structural properties during post-processing. Specifically, within the context of these devices, “monomers,” “oligomers,” “prepolymers,” and “polymers” refer to discrete molecular building blocks of increasing chain length that can tune the flexibility of imprinted features to prevent breakage during stamp release, or act as sacrificial templates that are burned out during calcination to intentionally induce porosity. “Alkoxides,” “metal oxide precursors,” and “sol-gel materials” denote reactive chemical precursors that can condense to form solid inorganic matrices or “metal oxides”—which are high-index inorganic compounds (such as TiO2, ZrO2, or HfO2) used to construct the primary nanoparticles or deposited via atomic layer deposition to backfill nanoscale pores. “Cross-linkable materials” designate substances capable of forming durable three-dimensional networks upon exposure to UV light or thermal treatment. A “transparent optical adhesive” describes a highly transmissive, curable formulation (such as Norland Optical Adhesive) used to physically bind structures without sacrificing absolute optical efficiency. An “insulating material” broadly describes a dielectric substance that resists electrical current flow, offering structural stability within the device stack. “Silanes” and “silane coupling agents” denote silicon-based molecules that form highly stable inorganic SiO2 linkages between adjacent particles, acting as physical barriers that suppress excessive grain size coarsening and surface roughening during high-temperature phase transformations. “Si-containing polymers,” “branched polymers,” “caged polymers,” and “silsesquioxanes” characterize specific geometric polymeric architectures that utilize steric hindrance to physically separate nanoparticles and restrict thermally driven particle fusing. A “metal-oxo cluster” (such as TiOC) refers to a discrete, molecularly defined metal-oxygen complex that can function as a high-index inorganic binder or even partially replace the primary inorganic nanoparticles within the dispersion.

As used herein, the term “in contact with” refers to a state of physical touching, immediate proximity, or chemical linkage between distinct building blocks within an imprintable formulation. In the context of the described optical devices, this term frequently describes the physical interaction between the primary solid components of the composition, such as a plurality of nanoparticles being positioned “in contact with” a binder material. This state of contact serves several structural and chemical purposes: it can indicate a physical interface where materials are densely packed to manage porosity for subsequent vapor-phase depositions, or it can denote direct structural reinforcement through the formation of chemical bonds and linkages between the nanoparticles and the binder. Moreover, placing nanoparticles in contact with specific binder materials allows the binder to sterically separate the nanoparticles, thereby intentionally hindering direct contacts between the nanoparticles themselves. Preventing these direct nanoparticle-to-nanoparticle contacts is essential during high-temperature thermal annealing to suppress excessive grain size coarsening, particle merging, and surface roughening. Being in contact with generally denotes a configuration where the surfaces of two distinct phases or materials meet without any intervening macroscopic space, enabling intermolecular forces, chemical interactions, or mechanical load transfer to occur across the shared interfacial boundary.

As used herein, the term “pore” refers to a minute void, air space, or interstitial gap located within the solid matrix of a material or imprinted composition. Within the context of the described advanced optical devices, a plurality of nanoscale pores is naturally formed and confined by the densely packed arrangement of nanoparticles in the deposited layer. The size, distribution, and diffusion path tortuosity of these pores can be carefully engineered by blending nanoparticles of different sizes; for example, formulating a mixture of 10 nm and 20 nm nanoparticles typically yields an average pore size in the range of 2 to 3 nanometers. Furthermore, porosity can be intentionally induced or expanded by incorporating sacrificial organic or polymeric binders into the formulation, which are later removed—such as through thermal calcination—to leave behind larger voids that act as a porous template. A purpose of engineering the size and distribution of these pores is to provide an accessible volume that can be efficiently and uniformly backfilled using vapor-phase processes, particularly atomic layer deposition (ALD). By replacing the empty air voids with high-index materials like metal oxides, the overall refractive index and optical density of the final patterned structures are significantly enhanced.

As used herein, the term “vapor phase” refers to the gaseous state of a substance, typically utilized as a highly diffusive medium to transport chemical precursors or deposition materials onto a substrate or into nanostructured features. To provide a broader scientific context common in chemistry and materials science, a vapor phase is generally defined as a thermodynamic state of matter consisting of a gas that can be condensed to a liquid or solid, which is widely used in thin-film deposition techniques to ensure conformal and uniform material coating. Within the context of the described advanced optical devices, vapor-phase depositions—such as atomic layer deposition (ALD), chemical vapor deposition (CVD), and evaporation—are frequently employed during post-processing and device fabrication. For example, vapor-phase deposition can be used to apply a fluorine-based surface modification to a patterned stamp material to mitigate interfacial adhesion strength, helping to prevent the breakage of high-aspect-ratio features during demolding. Furthermore, the highly diffusive nature of gaseous precursor flows in the vapor phase allows these materials to efficiently and uniformly penetrate the nanoscale interstitial gaps and pores confined by densely packed nanoparticles. This vapor-phase backfilling is used for increasing the refractive index and optical density of the final structures.

As used herein, the term “inorganic material” refers to the non-carbon-based substances or compounds that constitute the fundamental building blocks of an imprintable composition, particularly the primary nanoparticles and specific specialized binders. Within the context of the described advanced optical devices, utilizing inorganic materials is essential for creating structurally robust and thermally stable high-refractive-index structures; for instance, high-temperature calcination is frequently used to intentionally burn out sacrificial organics to leave behind a highly stable “all-inorganic structure.” Specific examples of inorganic materials forming the nanoparticles or utilized during atomic layer deposition (ALD) backfilling include high-index metal oxides and ceramics such as titanium dioxide (TiO₂), zirconium dioxide (ZrO₂), hafnium dioxide (HfO₂), niobium pentoxide (Nb₂O₅), barium titanate (BaTiO₃), tungsten disulfide (WS₂), aluminum oxide (Al₂O₃), silicon dioxide (SiO₂), and silicon carbide (SiC). Additionally, the term encompasses inorganic binders or precursors, such as metal-oxo clusters (e.g., TiOC) and silane coupling agents that form stable SiO₂ linkages, which act to sterically separate adjacent particles and suppress excessive grain size coarsening during high-temperature phase transformations. An inorganic material is defined as any chemical compound that lacks carbon-hydrogen (C—H) bonds, fundamentally encompassing minerals, metals, solid-state ceramics, and non-metals characterized by their high thermal stability.

As used herein, the term “atomic layer deposition” (ALD) refers to a highly precise vapor-phase thin-film deposition technique characterized by the sequential use of self-limiting gas-phase chemical reactions to deposit conformal materials with angstrom-scale thickness control. Within the context of the described advanced optical devices, ALD is critically utilized as a post-imprinting processing step to manipulate the physical and optical properties of patterned nanostructures. Specifically, due to the diffusive nature of its gaseous precursor flows, ALD is employed to efficiently and uniformly penetrate and backfill the nanoscale porosity, air voids, and interstitial gaps naturally formed by the densely packed nanoparticles. By selectively replacing these empty voids with high-refractive-index metal oxides—such as TiO₂, ZrO₂, HfO₂, Nb₂O₅, Al₂O₃, or SiO₂—this backfilling process significantly enhances the overall refractive index and optical density of the resulting device. Furthermore, owing to its ability to grow materials in self-limiting atomically thin layers, an additional ALD cladding step can be applied over the optical features to specifically smoothen surface roughness and uniformly fill in structural cracks caused by thermal shrinkage, thereby mitigating light scattering and preserving high optical efficiency.

As used herein, the term “precursor” generally refers to a reactive chemical compound or molecule that participates in a chemical reaction to produce another desired compound, solid material, or film. Within the context of the described advanced optical devices, the term frequently designates highly diffusive, gas-phase chemical reactants—specifically “ALD precursors”—utilized during atomic layer deposition (ALD) to form conformal thin films. During post-imprint processing, these precursors are introduced into a deposition chamber where they diffuse into and soak all the accessible structural features and nanoscale pores confined by the densely packed nanoparticles. After undergoing self-limiting surface reactions, the unreacted precursors and chemical byproducts are purged away, leaving behind a solid, high-index material that backfills the voids. Specific examples include metal oxide precursors used to deposit high-index inorganic materials such as TiO₂, ZrO₂, HfO₂, Nb₂O₅, Al₂O₃, and SiO₂. The fabrication process can strategically utilize an ALD precursor that matches the base inorganic material of the nanoparticles, different ALD precursor materials, or a co-deposition of a mixture of different precursors to finely tune the resulting refractive index of the patterned optical device. Furthermore, an additional cladding layer made from a different precursor can be deposited over the structures to protect them or smoothen surface roughness. Beyond vapor-phase deposition, the term also encompasses reactive liquid or sol-gel components added directly to the imprintable dispersion ink, such as “precursors to inorganic binders” or “metal oxide precursors,” which act as additives to chemically link the primary nanoparticles together prior to curing and high-temperature calcination.

As used herein, the term “organic material” refers to carbon-based compounds and substances that are incorporated into an imprintable composition, typically serving as temporary structural, chemical, or fluidic aids during the fabrication of an optical device. To provide a broader scientific context common in chemistry, an organic material is fundamentally defined as a chemical compound containing carbon, especially those featuring carbon-hydrogen (C—H) bonds, which encompasses a vast array of synthetic polymers, small molecules, and volatile solvents. Within the specific context of the described advanced optical devices, organic materials broadly encompass the ligands, binders (such as sacrificial polymeric binders or organic binders), low and high boiling point solvents, and any of their degraded byproducts that remain in the patterned structures after the initial UV or thermal curing process. Because the presence of these components can induce unwanted porosity or thermal instability in the final device, the imprinted composition is frequently treated to intentionally remove these “organic residues,” thereby transforming the patterned features into highly stable, all-inorganic structures. This removal of organic material is typically accomplished through post-processing treatments such as high-temperature calcination in an air environment, extended UV treatment, or O2-plasma ashing.

As used herein, the term “optically transparent” refers to the property of a layer, structure, or device that allows incident light of at least one specific wavelength—such as one or more ultraviolet, visible, or infrared wavelengths—to pass through it effectively. Within the context of the described advanced optical devices, achieving optical transparency simultaneously with a high refractive index is critical for ensuring high absolute efficiencies, because the onset of absorption in many conventional high-index materials typically decreases absolute efficiency. Formulations utilizing specific inorganic building blocks, such as ZrO2 and HfO2 nanoparticles, can produce patterned films that remain highly transparent even in challenging regimes like ultraviolet wavelengths. Optical transparency generally denotes a material's physical ability to transmit incident electromagnetic radiation without inducing significant macroscopic scattering, absorption, or wavefront distortion, thereby allowing light and optical data to be efficiently propagated.

As used herein, the term “metal oxide” refers to an inorganic chemical compound comprising at least one oxygen atom bonded to one or more metallic elements, typically exhibiting high thermal stability and structural robustness. Within the context of the described advanced optical devices, metal oxides are prominently utilized as high-refractive-index building blocks to formulate nanoparticle dispersions or as precursors for vapor-phase depositions. Specifically, the primary nanoparticles within the imprintable composition frequently include a metal oxide, with particular examples including titanium dioxide (TiO₂), zirconium dioxide (ZrO₂), hafnium dioxide (HfO₂), niobium pentoxide (Nb₂O₅), barium titanate (BaTiO₃), and aluminum oxide (Al₂O₃). Furthermore, metal oxides serve a critical role during post-imprint atomic layer deposition (ALD), where the nanoscale air voids and interstitial gaps naturally confined by the densely packed nanoparticles are uniformly backfilled with these high-index metal oxides to significantly enhance the overall refractive index and optical density of the final patterned features. Additionally, specific metal oxide precursors or discrete metal-oxo clusters (such as TiOC) can be incorporated directly into the formulation as structural binders to physically connect nanoparticles or to physically separate them in order to suppress excessive grain size coarsening during high-temperature thermal annealing.

As used herein, the term “spin-coat” (or “spin coating”) refers to a liquid-phase deposition technique used to form a uniform layer or film of an imprintable composition upon an underlying substrate. To provide a broader technical context common in the semiconductor and microfabrication industries, spin-coating generally involves depositing a small puddle of a fluid dispersion or resin onto the center of a substrate and then rotating the substrate at high speeds, utilizing centrifugal force to spread the fluid outward and form a thin, highly uniform coating. Within the specific context of the described advanced optical devices, performing a spin-coat is a critical initial step in the direct additive manufacturing process based on nanoimprint lithography (NIL), where nanoparticle dispersions or inks are applied to a substrate prior to the application of a patterned stamp. Historically, utilizing a spin-coating process with monodisperse nanoparticle formulations has presented significant challenges when attempting to produce the thick films (e.g., greater than 1 or 2 microns) necessary to fill in tall, high-aspect-ratio optical structures, frequently resulting in excessive cracking due to high structural shrinkage and residual stress. The described technology explicitly overcomes these spin-coating limitations by utilizing specially formulated dispersions comprising a blend of different-sized nanoparticles (such as 10 nm and 20 nm sizes) and low-viscosity binders; this optimized blending maximizes the particle packing density during the spin coating process, maintains necessary fluidity, reduces shrinkage, and ultimately enables the successful deposition of thick, crack-free layers for meta-optics.

As used herein, the term “patterned stamp” refers to a mold or templating tool utilized during nanoimprint lithography to physically transfer and form nanostructured or microstructured features onto a deposited layer. Within the context of the described additive manufacturing process, the patterned stamp is applied to the surface of the spin-coated nanoparticle composition and is specifically configured to form high-aspect-ratio features by drawing the fluidic dispersion into its narrow channels via capillary action. To maintain high-resolution pattern fidelity while providing the necessary mechanical flexibility for demolding, the patterned stamp is frequently comprised of a hybrid elastomeric material, such as a hybrid polydimethylsiloxane (PDMS) construct. This hybrid configuration typically features a harder material (e.g., hard PDMS or hPDMS) positioned immediately adjacent to the imprinted layer to support fine nanoscale geometries, which is structurally backed by a softer, thicker PDMS material. Furthermore, the patterned stamp includes a backing substrate—such as flexible PET sheets or rigid, oversized glass—which dictates the release angle and mechanical dynamics when removing the stamp from the cured structures. To prevent the breakage of delicate features during this release step, the surface of the patterned stamp can be chemically modified, such as with a fluorine-based vapor-phase or liquid-phase deposition, to lower the interfacial adhesion strength. A “stamp” or “mold” in nanoimprint lithography generally describes any master template—often fabricated from silicon, fused silica, quartz, or elastomeric polymers—that contains a predefined negative topological pattern used to mechanically imprint a complementary positive pattern into a deformable resist or resin under controlled pressure.

As used herein, the term “capillary action” refers to the physical phenomenon driving the flow of a liquid or dispersion into narrow channels, cavities, or constrained spaces. Within the specific context of the described additive manufacturing process, capillary action operates as the primary filling mechanism during the direct nanoimprinting process, where a fluidic nanoparticle dispersion is drawn into the very narrow channels of a patterned stamp. This dynamic mechanism is essential for shaping and forming high-aspect-ratio features on the surface of the deposited layer. Because pulling a fluid into such deep, nanoscale cavities inherently involves very strong shear and extensional flows, this capillary action-based filling process is closely tied to the viscosity of the imprintable dispersions. Formulations that deliberately blend different-sized nanoparticles can significantly lower this viscosity, thereby facilitating a more efficient and complete filling of tall nanostructures via capillary action. Capillary action (or capillarity) is defined as the ability of a fluid to flow within narrow spaces without the assistance of—or even in opposition to—external forces like gravity, a process driven primarily by a combination of adhesive intermolecular forces between the fluid and the solid surface, along with the cohesive surface tension of the fluid itself.

As used herein, the term “release angle” refers to the specific geometric angle or peeling angle formed between a separating master mold and the underlying substrate as the mold is continuously detached from the newly cured imprinted layer. Within the context of the described additive manufacturing process, controlling the release angle, along with release speed and force, is a critical parameter to successfully fabricate high-aspect-ratio optical features and avoid breaking or undercutting them during the demolding step. The release angle is fundamentally based on and dictated by the mechanical flexibility of the backing substrate that supports the patterned stamp. For instance, utilizing a highly flexible backing material, such as polyethylene terephthalate (PET) sheets, allows the stamp to be peeled away at a larger release angle compared to using a less flexible, rigid backing substrate like glass. When a rigid backing like glass is required, a sufficient release angle can still be achieved by oversizing the glass backing relative to the pattern size or the wafer size. Nevertheless, this parameter must be carefully optimized; if the release angle is too high, the mechanical stress concentrated at the separation interface can cause the delicate, high-aspect-ratio nanofeatures—or the stamp materials filling the gaps between them—to break during the stamp release process.

As used herein, the term “backing substrate” refers to the foundational support layer or structural carrier that is attached to and mechanically supports a patterned stamp during the direct nanoimprinting process. Within the context of the described additive manufacturing technology, the physical properties of the backing substrate—particularly its mechanical flexibility—fundamentally dictate the release angle and mechanical dynamics when detaching the patterned stamp from the newly cured optical structures. For instance, utilizing a highly flexible backing substrate, such as polyethylene terephthalate (PET) sheets, allows the patterned stamp to be peeled away at a larger release angle. Conversely, utilizing a less flexible, rigid backing substrate, such as glass, requires different design considerations; to achieve a sufficient release angle with a harder backing material, the glass backing can be intentionally oversized relative to the pattern size or the underlying wafer size. A backing substrate is defined as the thick, load-bearing foundational layer of a composite mold (such as a hybrid elastomeric stamp) that provides macroscopic mechanical stability, facilitates manual or automated handling, and ensures uniform pressure distribution across the stamp interface during the imprinting process.

As used herein, the term “hard PDMS material” (or hPDMS) refers to a specialized formulation of polydimethylsiloxane engineered to exhibit a higher elastic modulus and structural stiffness compared to standard, softer PDMS elastomers. Within the context of the described additive manufacturing process, a hard PDMS material is frequently utilized as the high-resolution, pattern-defining contact layer within a hybrid elastomeric stamp (an hPDMS/PDMS construct). In this hybrid configuration, the hPDMS material is positioned directly adjacent to the surface of the imprinted layer to form the optical features, while being structurally backed by a softer, thicker PDMS material. The primary structural purpose of the hard PDMS material is to withstand imprinting pressures without excessive deformation, which is critical to support the precise patterning of high-aspect-ratio features. The modulus of this material can be explicitly tuned by changing the composition of its mixing components, crosslinking density, or elements in the polymer backbones. Furthermore, the physical thickness of the hard PDMS material must be carefully optimized; if it is too thin, the imprinting pressure exerted onto the softer PDMS backing leads to the excessive deformation of the hPDMS layer itself, preventing the successful fabrication of tall, high-aspect-ratio optical structures. Fabrication methods may also involve adjusting the thickness ratio between the softer PDMS material and the hard PDMS material based on the specific pattern density of the target features.

As used herein, the term “pattern density” refers to the relative concentration, spacing, or area fraction of structural features distributed across a specific region of a substrate or device layer. Within the specific context of the described additive manufacturing processes, pattern density fundamentally describes how closely placed the high-aspect-ratio nanostructures or microstructures are to one another, which inherently dictates the size of the gaps, vias, or interstitial spaces separating them. The pattern density of the target features is a critical device design parameter that significantly impacts their successful imprintability. If the pattern density is too high—meaning the features are positioned too closely together—the gaps between them become very tight, which in turn reduces the physical thickness of the stamp material filling those interstitial spaces during imprinting. As a result, the excessively thin stamp material may lack sufficient mechanical strength to properly support the adjacent features, leading to an increased risk of breaking the delicate, high-aspect-ratio structures during the demolding process. To accommodate varying pattern densities and prevent feature breakage, the physical dimensions of the patterned stamp must be carefully optimized; for instance, the fabrication method can include dynamically adjusting the ratio of the thickness of a softer PDMS backing material to the thickness of a harder hPDMS contact layer based directly on the specific pattern density of the at least one feature.

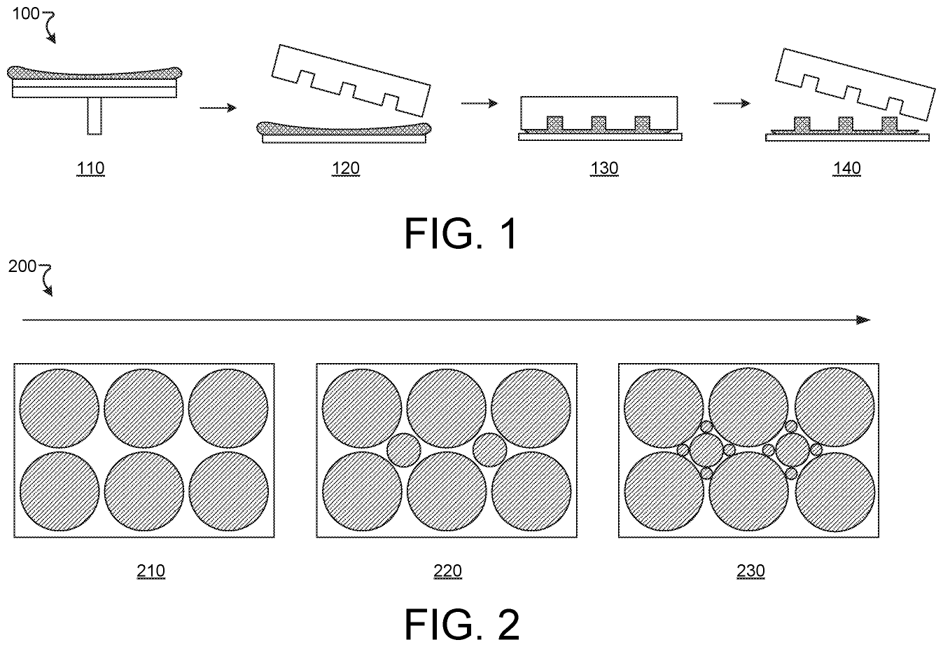

FIG. 1 is a diagram illustrating an example direct patterning process 100 of nanoparticle-based dispersions based on nanoimprint lithography. The process 100 begins with the application of an imprinting material 120, such as a formulated nanoparticle dispersion, onto an underlying substrate 110. This deposition is accomplished through a spin-coating process, which spreads a uniform film of the imprinting material 120 across the surface of the substrate 110 in preparation for the subsequent lithographic molding steps.

Following the initial spin-coating stage, the process advances to the patterning of the spin-coated film, wherein a patterned stamp material 130 is brought into physical contact with the fluidic imprinting material 120. This contact allows the dispersion to fill the narrow cavities of the mold and accurately form the targeted nanostructured or microstructured features. Once the requisite features are physically shaped, the complete assembly is cured in place. The direct patterning process then concludes with the mechanical removal or demolding of the stamp material 130, successfully leaving behind the fully formed cured structures 140 securely adhered to the substrate 110.

FIG. 2 is a diagram illustrating an example schematic description 200 of increasing particle density by adding different sized particles. Different sizes of particles of the same kind or a different kind can be mixed to increase the packing density of particles shown in 210. Polydispersed particles as shown in 220 and 230 can fill in gaps more efficiently than monodispersed particles in 210. Adding small binders or additives provide a similar effect in terms of volumetric fill factor as the inorganic hard particles to make a denser structures and ultimately achieve a higher refractive index.

Blending two or more different-sized nanoparticles or binders as in 230 in the formulation is can not only be beneficial in maximizing the particle packing efficiency but can also be advantageous in facilitating the filling mechanism of the high AR nanofeatures in the stamp material. This can be explained by the Farris Effect, which describes the decrease of the viscosity of a suspension upon increasing the dispersity of the solid additive like nanoparticle, at the constant volume fraction of the solid additive. That is, a broader particle size distribution yields a lower viscosity than a narrower particle size distribution, for the same concentration of particles, whenever suspensions are flowing, particularly for suspensions with high loading fractions. This effect can be employed to this direct nanoimprinting approach where the filling mechanism is based on the capillary action of nanoparticle dispersions into the very narrow channels of the high AR structures which accompany very strong shear and extensional flows. For example, a binary mixture of two different-sized nanoparticles enables can enable an easier and more complete filling of high AR structures than the dispersion comprising a single size.

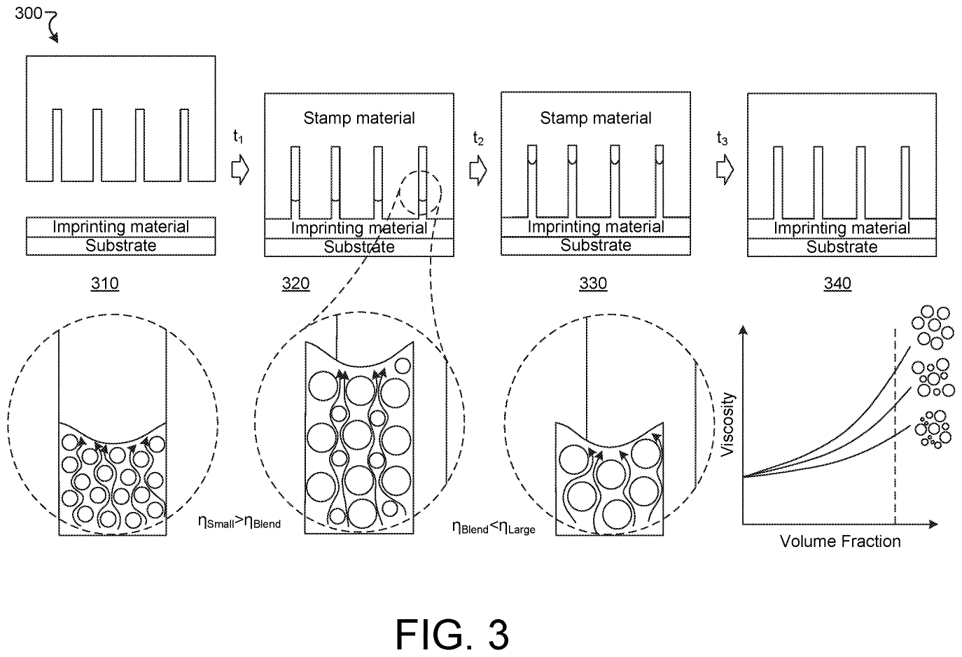

FIG. 3 is a diagram illustrating an example schematic description 300 of the effects of particle size distributions on the viscosity of the particle dispersion and the filling mechanism through narrow channels in a stamp. FIG. 3 shows the effects of blending two or more different-sized particles onto the flow behavior. This capillary action-based filling mechanism of nanoparticle dispersions into a patterned stamp 310 with high AR nanofeatures is related to the viscosity of the dispersions. Since this filling process takes place when the stamp makes a contact with a spin-coated film at 320, a shear rate or an extensional flow rate can be expected to be large, meaning that the shear-dependence of the viscosity can become important. The so-called Farris effect that a broader particle size distribution yields a lower viscosity than a narrower particle size distribution becomes more dominant at this flow rate regime, particularly with high nanoparticle loadings. As shown in FIG. 3, the dispersion with two particles yielding a lower viscosity can be expected to fill in high AR features and tall features, as shown at 330 and 340, more quickly and completely.

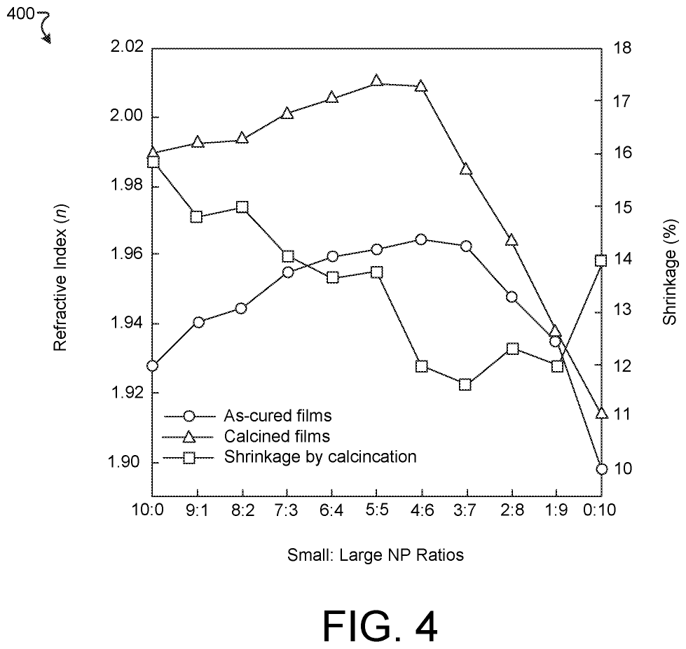

FIG. 4 is a diagram illustrating an example plot 400 of refractive index and film shrinkage of as-cured and calcined films at varying blending ratios of 10 nm and 20 nm TiO2 nanoparticles. FIG. 4 illustrates the effects of blending two different-sized TiO₂ nanoparticles (10 and 20 nm on average) on the refractive index at 543 nm. The blending ratio of the two different size particles is varied from 10:0 (10 nm:20 nm) to 0:10. It is revealed that the two particles show a synergistic effect in terms of refractive index due to an increased packing density by mixing. The maximum refractive index is observed at around the 4:6 ratio for both as-cured films and calcined films at 450 °C. The overall refractive indices are shifted to higher values upon the calcination due to the densification process of the particles and removal of organic residues in the as-cured films. The ratio yielding the maximum refractive index stays the same even after calcining the films. It should also be mentioned that the shrinkage of the films during the calcination also shows minima at ratios around 4:6 and 3:7, which mirrors the trend of the refractive index graphs. This indicates that having a better particle packing in the cured structures would undergo less shrinkage during the thermally driven rearrangement and densification of particles because the particles were already more densified during coating or patterning.

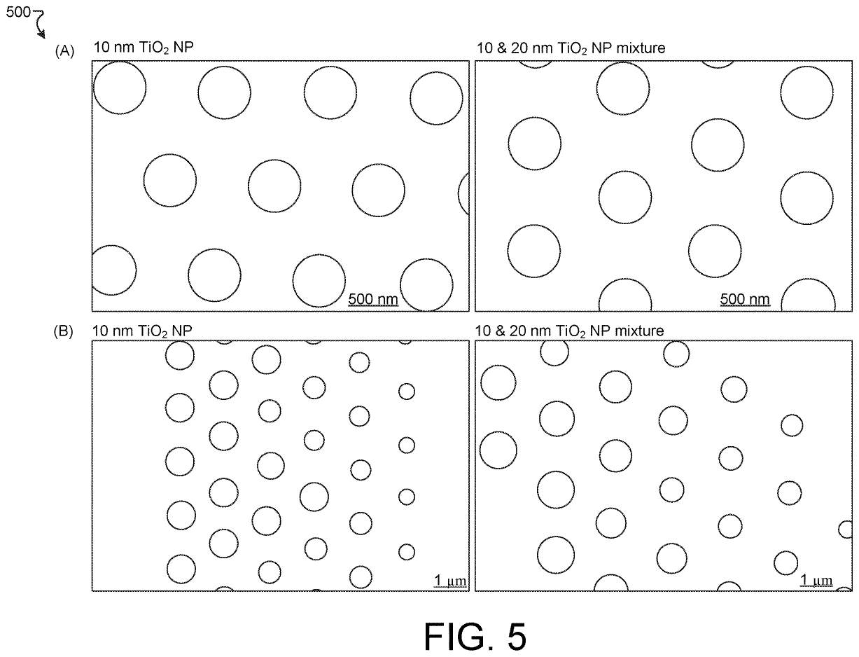

FIG. 5 is a diagram illustrating example top-down scanning electron microscope (SEM) images 500 of nanopillars fabricated with TiO2 dispersions, demonstrating reduced crack formation by mixing different sized particles. Top-down SEM images 500 shown in FIG. 5 verify the reduced crack formation in patterned structures with circular pillars during the calcination by mixing two different sized particles. This result is due to the hard packing theory where particles of a certain ratio are able to fill voids between larger particles, comparable to gravel and sand. The two lower RI components can either be the combination of two different-sized nanoparticles or the combination of a nanoparticle and a binder. A binder system can also be composed of one or more binder elements. Also, broadening the size distribution of nanoparticles or binders can also lead to a higher packing density. A three-part blend of two different-sized nanoparticles and a binder can also lead to a higher packing density if the size difference of the three components is suitably adjusted to maximize the packing density. The increased packing leads to a higher gravitational and optical density that can provide advantages in both the design and final implementation of these optical devices. In many cases, an increase in the limit of accessible RI simplifies design parameters such as AR and in other cases, the higher RI provides a greater FOV for holographic elements and collimating beam splitters or greater NA and resolution for metalenses and flat-top beam shapers. In addition, the more perfect packing of components including nanoparticles and binders during the spin coating and the imprinting process can be beneficial in terms of the dimensional shrinkage of the imprinted features relative to the dimensions of the master mold. Reducing the feature shrinkage can play a role in NIL-based fabrication platforms because the feature dimensions of the master mold are determined based on the shrinkage and the reduced shrinkage provides more design freedom of the master. The more perfect packing of building blocks during the imprinting step can also reduce any RI and dimensional losses during the post-imprint process such as calcination. An imprinting material with a lower shrinkage such as a blend of the 10 nm and 20 nm TiO₂ NPs can make better imprinted structures up to a few micron-scale without forming any large cracks, which can be beneficial for the optical devices designed for the IR wavelength ranges. This is another parameter to increase the efficiencies of the fabricated devices because cracks resulting from feature shrinkages contribute to the scattering and loss of the light to an undesired way in terms of focusing and splay of the light.

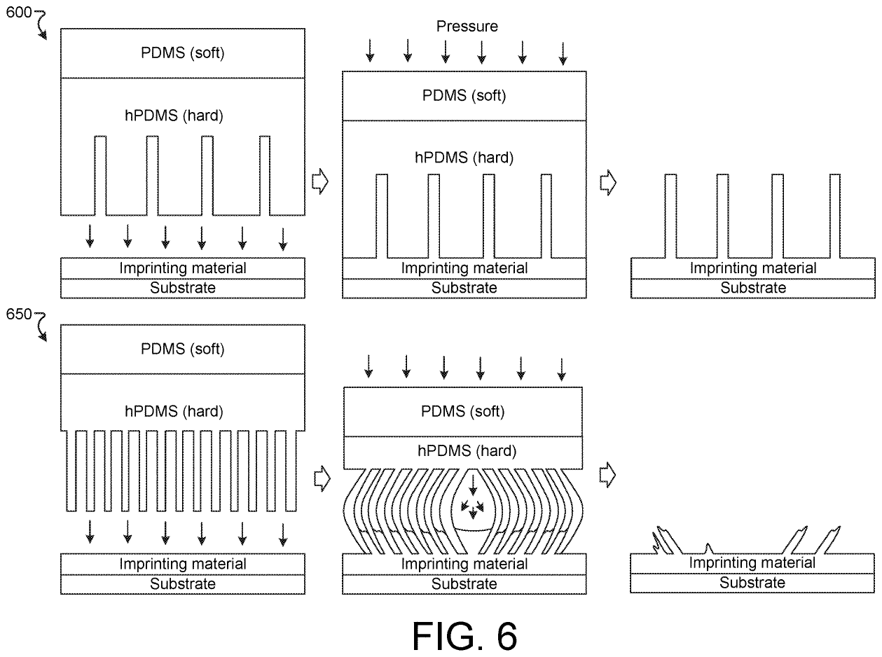

FIG. 6 is a diagram illustrating an example schematic description 600 and 650 showing the effects of the device design on the imprintability of high aspect ratio features based on pattern density. The design parameters of optical devices such as the density of the high AR features are also related to the successful fabrication of high AR features as shown in 600. However, a gap, via, or space between high AR features plays a role because if they are too closely placed with one another, as shown in 650, the chance of breaking the high AR features can increase. Such a breaking may occur because the tighter gap between high AR features in return means that the thickness of the stamp material filling in that gap becomes smaller. The stamp material may not provide mechanical strength strong enough to support the adjacent high AR features, which leads to the breakage of high AR features during the direct nanoimprinting method. If the gap between high AR features filled in by the stamp material is wide enough, the stamp may properly fabricate and support the high AR features around it.

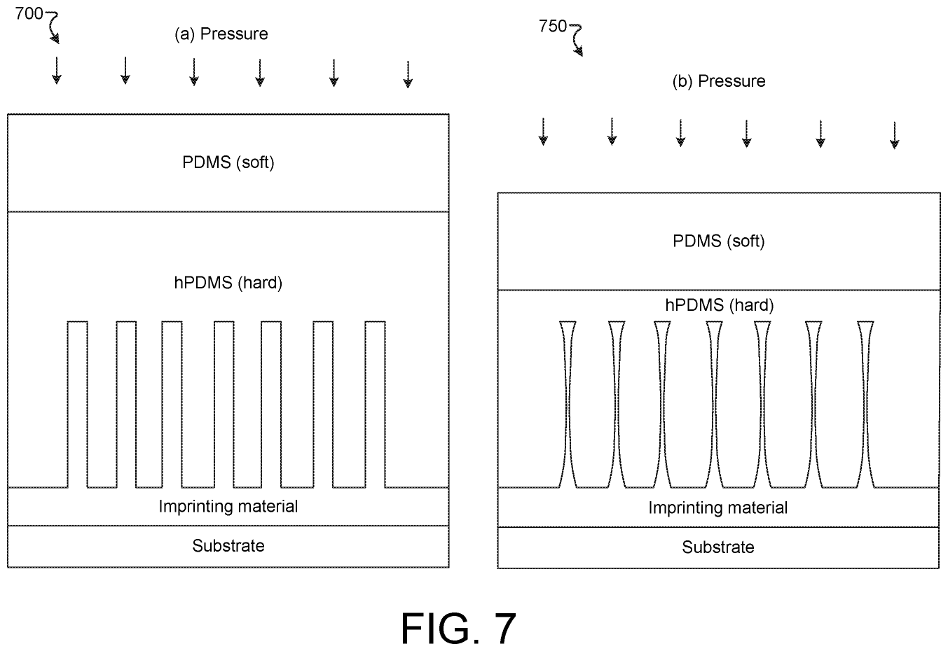

FIG. 7 is a diagram illustrating an example schematic description 700 and 750 comparing the effects of the hard PDMS (hPDMS) layer thickness on the fabrication of high aspect ratio features. In addition to the design, tuning the properties of stamp materials and imprint materials can play a role in achieving high AR features. The interfacial adhesion strength between stamp material and imprinted structures can be mitigated by using fluorine-based surface modification to fabricate high AR features. This strategy can be accomplished either by adding a fluoro-based surfactant to the imprinting material or by modifying the surface of the stamp material or a combination thereof. The surface modification of the stamp material can be done either by vapor-phase deposition or by liquid-phase spin coating. The modulus of the stamp material can also be tuned by using different stamp materials to fabricate high AR features. For example, the modulus of PDMS-based stamp materials can be tuned by changing the composition of the mixing components, crosslinking density, elements in polymer backbones, etc. The thickness of the stamp material can also be tuned. For example, the thickness of the hard PDMS (hPDMS) layer in the hybrid stamp (hPDMS/PDMS) can be increased, as in 700, to support the patterning of high AR features. If the thickness of the harder hPDMS layer gets too thin, as in 750, the imprinting pressure exerted to the softer PDMS layer leads to the excessive deformation of the hPDMS layer underneath as well as the PDMS layer, which will prevent the successive fabrication of high AR features.

The speed, angle, and direction (for asymmetric feature shapes or designs) of the stamp release process are also related to the successful fabrication of high AR features by preventing their breakage during the stamp release step. The flexibility of the backing substrate of the stamp material can be changed by using a different backing substrate such as PET sheets, which helps release a stamp at a larger release angle, compared to the less flexible backing substrate such as glass. In case of harder backing materials like glass, a sufficient angle can be created by oversizing the glass backing than the pattern size or the wafer size. If the release angle is too high; however, high AR features can also be broken during the stamp release process or the stamp materials filling the gaps between the high AR features can be broken during the release at high release angles. Adhesion promoters can be used to enhance the adhesion strength between the imprinted structures and the substrate underneath. The adhesion strength at the imprint-substrate interface may be strong enough to overcome the adhesion strength between the imprinted structures and the stamp because the adhesion gets stronger as the AR of features increases at the given device size and other design parameters fixed. The increase of the adhesion strength at the imprint-substrate interface can help avoid the breakage of high AR features or the delamination of the imprinted structures from the substrate during the stamp release process.

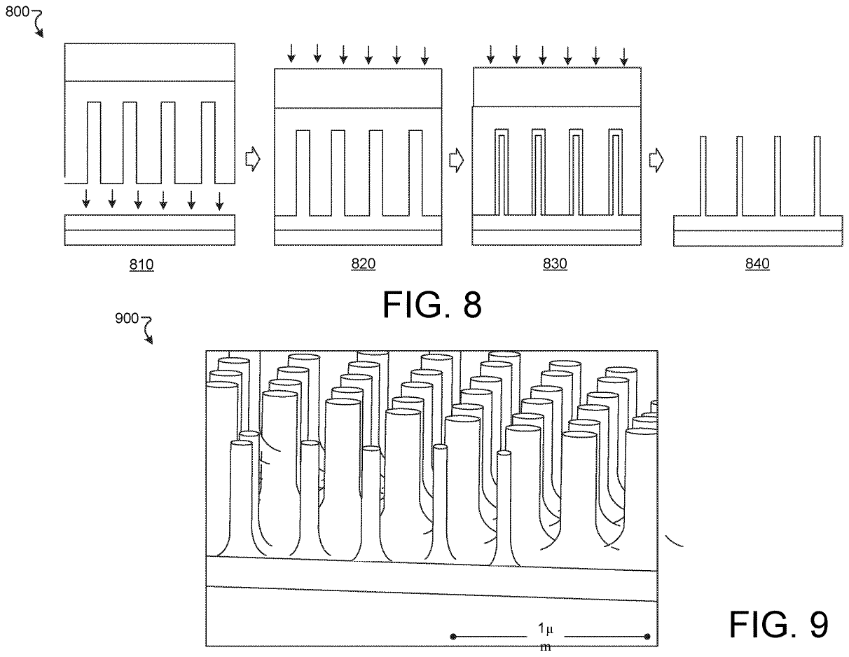

FIG. 8 is a diagram illustrating an example schematic description showing the effects of a two-step curing process 800 on feature shrinkage to enable an easier release of the stamp. As shown in FIG. 8, at 810 a patterning stamp is applied to an imprinting material; at 820, once the patterning stamp is in contact with the imprinting material at 820, pressure is applied to the PDMS layer of the patterning stamp A larger gap between the stamp and the imprinted features made by a larger shrinkage of imprinted structures can help reduce the physical and chemical adhesions/interactions between the stamp and the imprinted features. The shrinkage of imprinted structures can be increased or decreased by binder identity, particle size selection, ligand structures of particles, etc. The shrinkage of imprinted structures can also be increased during the imprinting process by using an extended UV exposure during the UV curing process at 830 before releasing the stamp from the imprinted features at 840. A small amount of solvents can be inserted to the release interface to mitigate the release force with a specific solvent that only softens the stamp material, not the cured structures, and that can be removed afterwards through drying.

The modulus of the imprinted feature can be tuned either by selecting a different binder or by changing the amount of binders. For example, using pre-polymers/polymers/Si-containing polymers as binders can reduce the stiffness of the imprinted structures and can be more tolerant to the mechanical stamp release process, which prevents the breakage of high AR features. This softening of the imprinted features can be later modified to make them harder through post processes such as calcination in air, UV ozone treatment or extended UV exposure to remove organics and polymers. Nanofeatures prepared with such sacrificial binders can also be structurally supported afterwards by using the post-imprint atomic layer deposition (ALD) process to backfill the porosity made by the sacrificial binders.

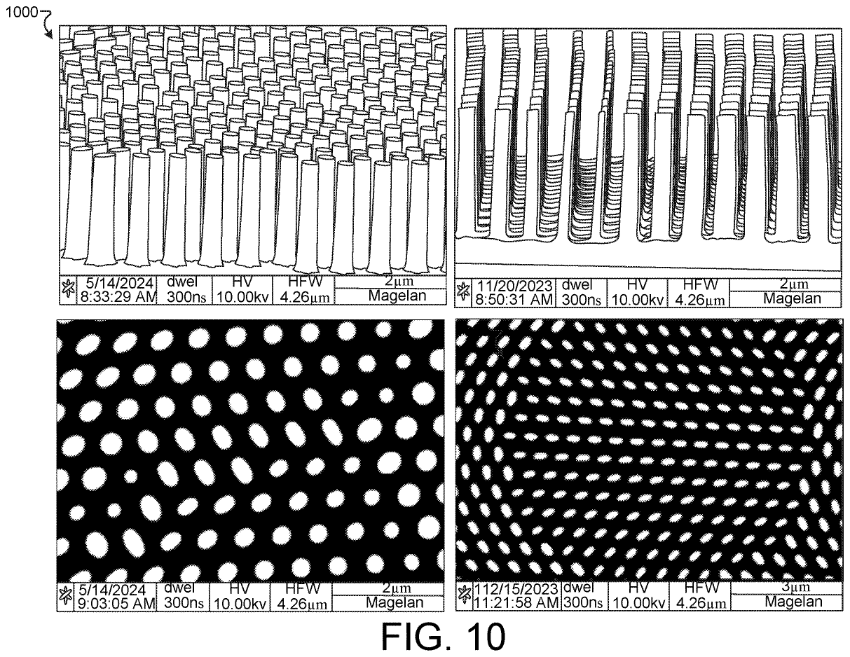

FIGS. 9-11 shows some examples of directly printed structures with the AR greater than 10. FIG. 9 is a diagram illustrating example nanostructures 900 fabricated by direct NIL with an aspect ratio greater than 10. FIG. 10 is a diagram illustrating example nanostructures 1000 fabricated by direct NIL with an aspect ratio greater than 15 and a height greater than 1 μm. The images shown in FIGS. 9-11 also demonstrate a fabrication of pillars with asymmetric shapes. This asymmetric aspect ratio, where the pillar has different widths in two directions, becomes critical in metasurfaces that interact with different polarizations separately. Breaking the symmetry of the posts enables a phase delay for one polarization and another for a second polarization, since each incident polarization interacts with a different width, and resultant phase delay. Utilizing these principles, metasurfaces can be designed and fabricated to focus or splay individual polarizations to specific locations on a detector or display, retaining a quantity of optical data. This type of performance can be compared with that in traditional optics, where for example a combination of a lens and a wire grid polarizer filters out 50% of the polarizations. The wire grid polarizer alone can lose much of the optical data, which can be retained by polarization-controlled lenses in meta-optics. Polarization-controlled metalenses can be fabricated by subtractive processing in Si, but the absolute efficiencies are limited by the absorption profile of Si in the visible and the cost of the subtractive process including patterning, etching, and resist removal. Coupling the material set used for direct NIL with the high ARs used by polarization-controlled metalenses is employed in these novel devices in imaging and sensing.

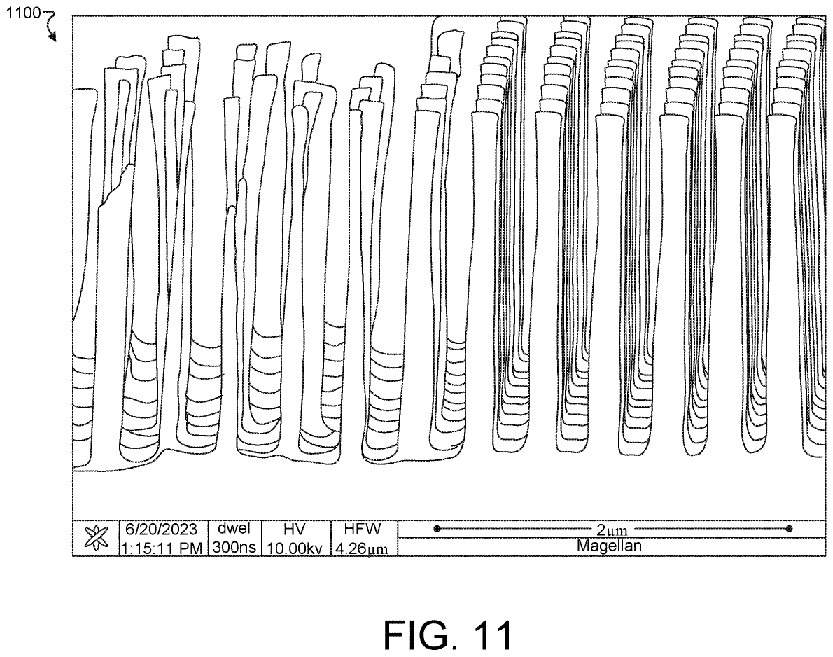

FIG. 11 is a diagram illustrating example nanostructures 1100 fabricated by direct NIL with an aspect ratio greater than 20 and a height greater than 2 μm. This high pillar height greater than 2 μm along with the high ARs has not been achieved by direct NIL-based approach. This may be because while pre-polymers or polymers are binders holding NPs they are viscous, limiting the accessible pillar height. Even if other small-molecule binders are used to lower the viscosity, a monodisperse nanoparticle formulation has a certain limit in terms of film thickness based on the spin-coating process because its high shrinkage and resulting residual stress lead to excessive cracking upon curing of the films and imprinted structures. By using the blended formulation of two or more different-sized particles with the low-viscosity binder, a thick film required for pillar heights greater than 2 μm is accessible owing to the reduced shrinkage as described above and owing to the reduced viscosity helping the capillary action into the narrow, tall features as described above.

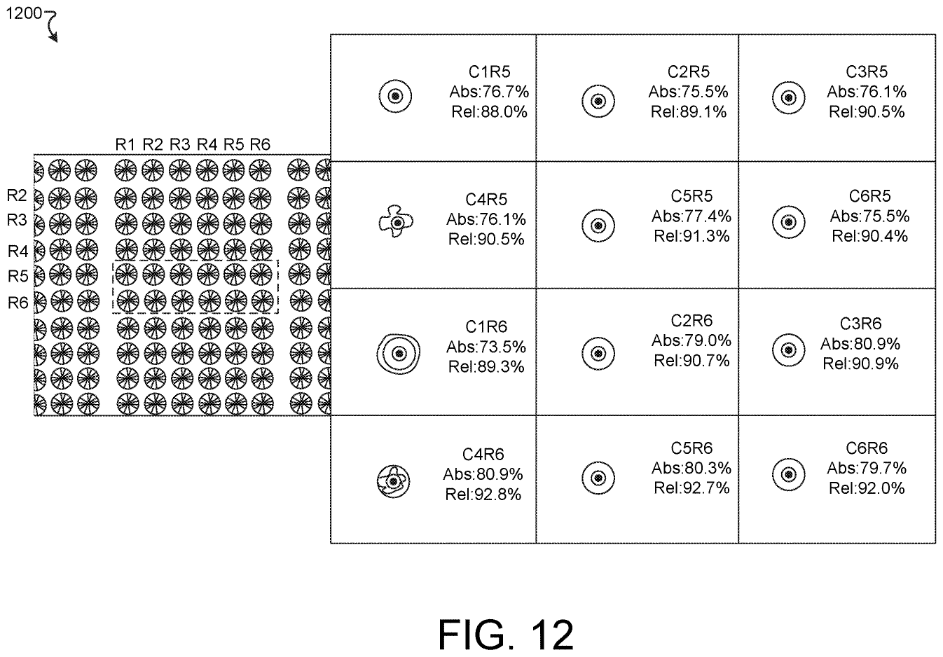

FIG. 12 is a diagram illustrating example metalenses 1200 operating in visible wavelengths with absolute efficiencies exceeding 80% and relative efficiencies exceeding 90%. In meta-optics, not all efficiencies are the same. For DOEs, efficiencies are generally a ratio of powers. One efficiency is absolute efficiency, where the power going into the device, incident to one side, is the denominator. For metalenses, the numerator is the focused power going through the focal spot, masked by a small pin hole to block any remaining, scattered or stray light. For holographic or dot projecting optical elements, the numerator is the sum of the power going to the display or individual dots, respectively. Absolute efficiency is commonly adjusted in order to account for Fresnel reflectance, normalizing the value depending on the RI of the used substrates without anti-reflection coating. The Fresnel-corrected absolute efficiency is an effective way to compare efficiencies of devices since it accounts for all the losses taking place in the optical devices from entry to exit. In practice, the Fresnel-corrected absolute efficiency is the predicted value for a meta-optics where the backside of the substrate is anti-reflection coated, which would be the design for a real-world device.

In addition to absolute efficiency, relative efficiency provides significantly higher values. Relative efficiency utilizes the same numerator for the different devices outlined above, but instead of being divided by total incident power, it is divided by transmitted power out of the surface of an optical device. Therefore, relative efficiency ignores the losses such as backscattering, reflection and most importantly, absorption. The transmitted power can be attenuated in any number of ways, but is always lower than the incident power, inflating relative efficiency and circumventing properties that are critical to the final device's performance.

For NP composites, comprised of transparent nanoparticles, the high absolute efficiencies are achieved despite the fact that it has been difficult to achieve transparency and high RI at the same time. For many high RI materials, the onset of absorption decreases the absolute efficiency due to absorption, but does not greatly reduce the relative efficiency, since that measurement normalizes out the absorption losses.

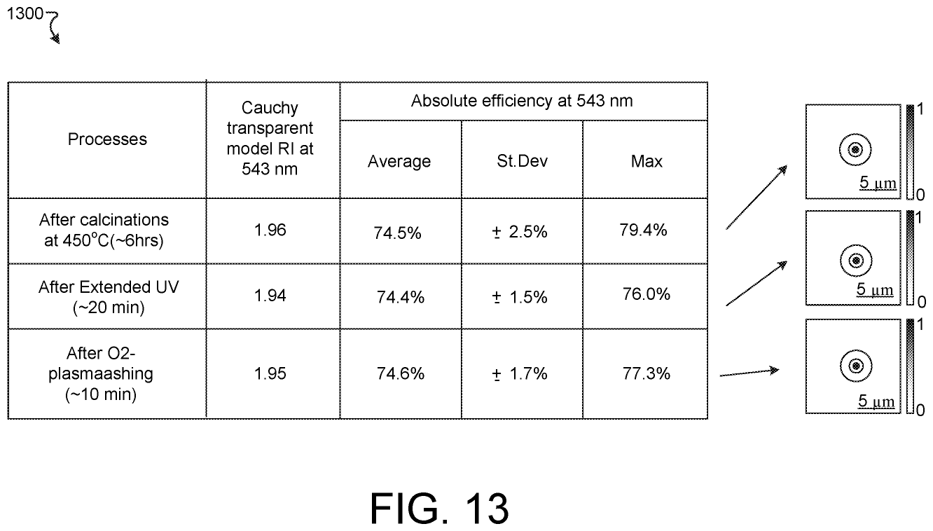

FIG. 13 is a diagram illustrating an example chart 1300 of absolute efficiencies of metalenses processed with different methods of organic removal after imprinting. The removal of any organic residues can be completed by other means in addition to the calcination. The methods give similar absolute efficiencies and good diffraction-limited focal spot images at the focal plane. The removal of organics can be verified by FTIR analysis of the films that are processed in the same conditions.

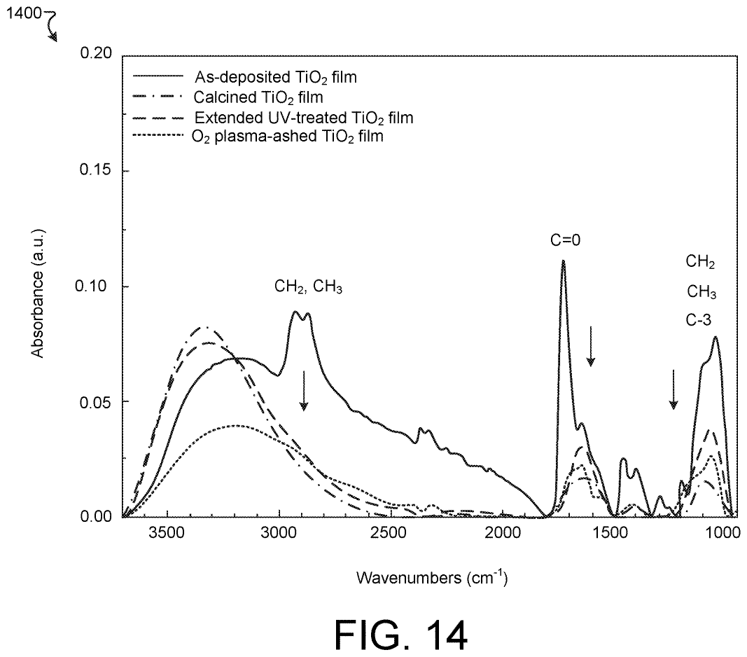

FIG. 14 is a diagram illustrating an example plot 1400 of FTIR graphs of the planar films processed through different methods to verify the removal of residual organics. As shown in FIG. 14, the peaks assigned to the residual organics detected with the as-cured film can disappear upon the different post-processing methods. The extended UV and O₂-plasma ashing methods can be superior to the high-temp calcination method in terms of processing temperatures. These low-temperature methods can be expected to reduce feature shrinkages taking place at high temperatures and the formulation of large cracks resulting from any thermally-driven evaporation of residual organics through narrow gaps between NPs. Also, these low-temperature approaches can be beneficial for patterning on high-index glass substrates which are known to be thermally unstable at the moment. Reducing any mismatches in thermal expansion coefficients between imprinted structures and substrate materials is also expected to reduce the resulting cracks.

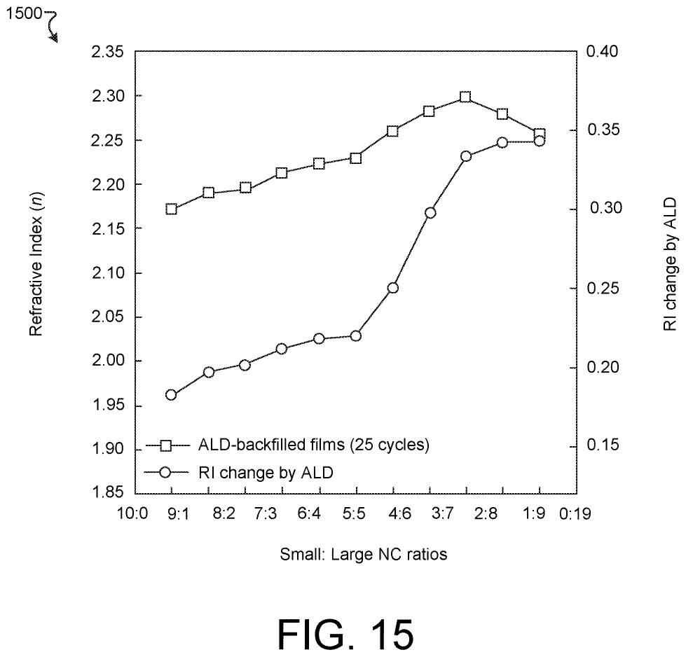

FIG. 15 is a diagram illustrating an example achievement 1500 of a high refractive index up to 2.3 utilizing two particle sizes combined with calcination and ALD. Another benefit to the NP/Binder approach to the direct printing of meta-optics is the optional post processing by atomic layer deposition (ALD). While the directly printed RI increase contributes to advantages for the termed “as-imprinted” devices, an additional RI boost by ALD can provide a further degree of increase and advantage as shown in FIG. 15. Combined, the increased packing from the NP blends and the RI increase from ALD can provide the highest RI to date for these direct NIL processable material at 2.30 at 543 nm.

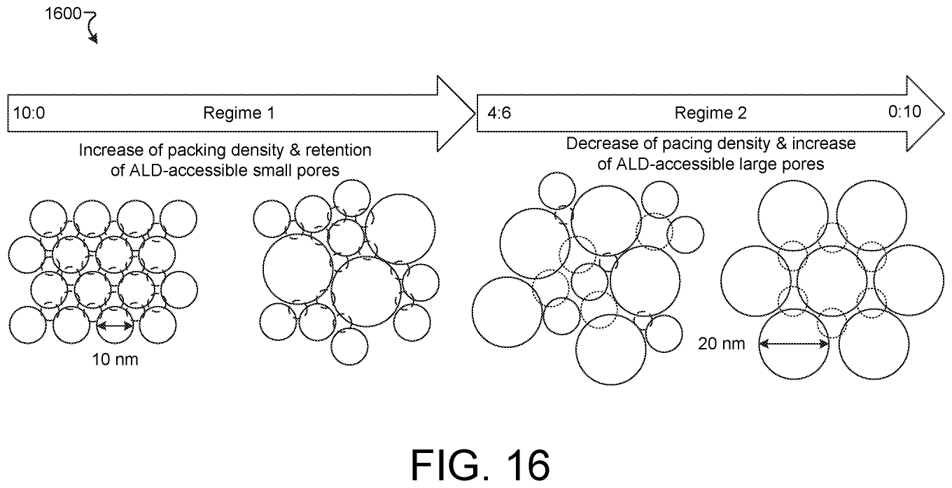

FIG. 16 is a diagram illustrating an example schematic description 1600 showing the effects of blending two different-sized particles on the accessible pores for the atomic layer deposition process. FIG. 16 shows that the ALD backfill process onto the films prepared from a mixture of two different-sized TiO2 nanoparticles can result in the increase of RI as high as 2.30 at a certain mixing ratio of the two particles.

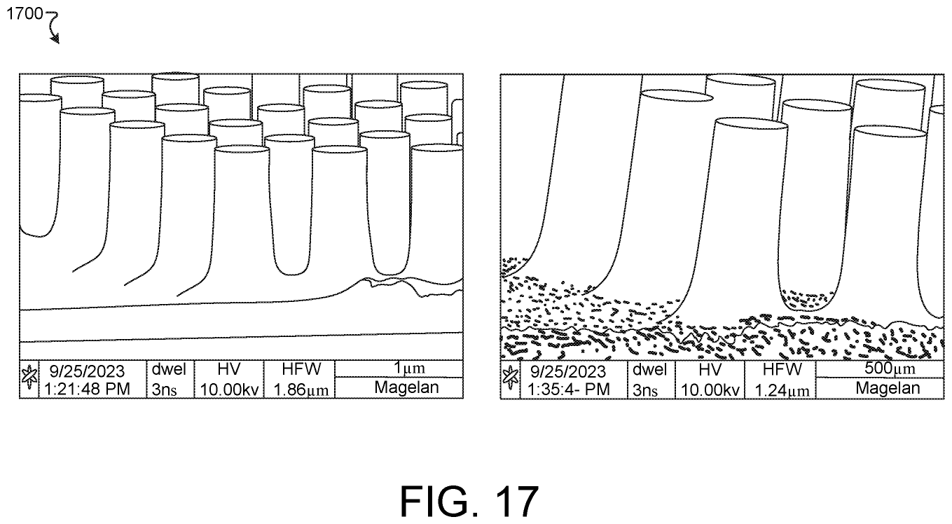

FIG. 17 is a diagram illustrating example SEM images 1700 of metalens structures where a sacrificial NOA binder induces porosity during calcination. The rationale behind the more advantageous RI boost at specific nanoparticle sizes and ratios can be attributed to the change in the size and distribution of pores between nanoparticles due to the denser packing in the particle-blended structures. The larger pores formed by larger nanoparticles can provide an increased volume to be backfilled by ALD and can reduce the tortuosity of the ALD diffusion path. The porosity of the imprinted structures can also be tuned either by increasing the size of inorganic nanoparticles or by using organic or polymeric binders which can be removed and leave pores. The larger pores can be backfilled by more deposition cycles of ALD, resulting in a higher end RI and getting closer to the RI of the bulk inorganic material. FIG. 17 shows an example of using a polymer as a binder that can be removed by calcination and leave large pores. In the figure, the SEM images are compared for the as-imprinted and calcined metalens structures prepared with a TiO2-NOA composite ink. A more porous structure is found after the calcination due to the elimination of the NOA binder leaving pores.

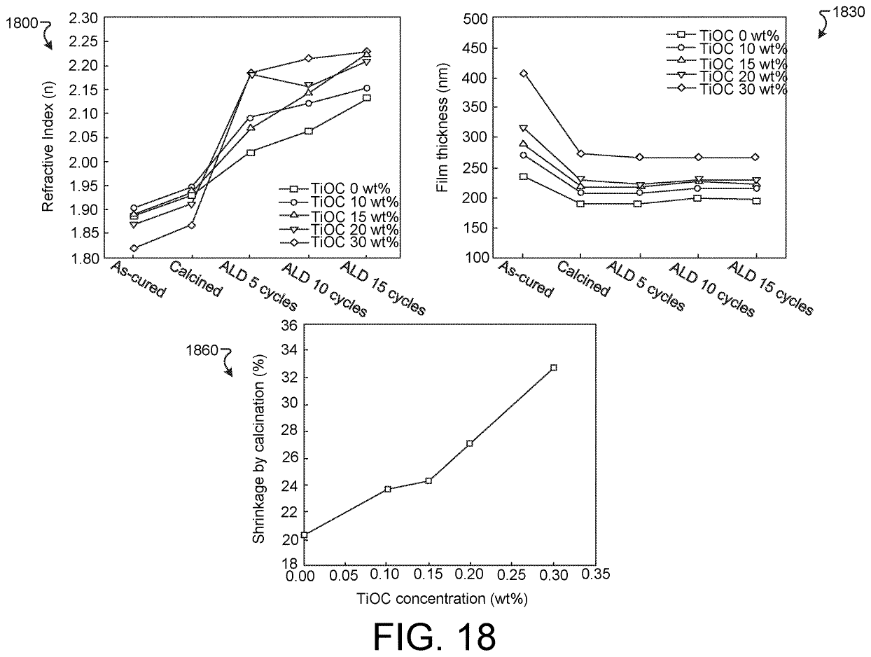

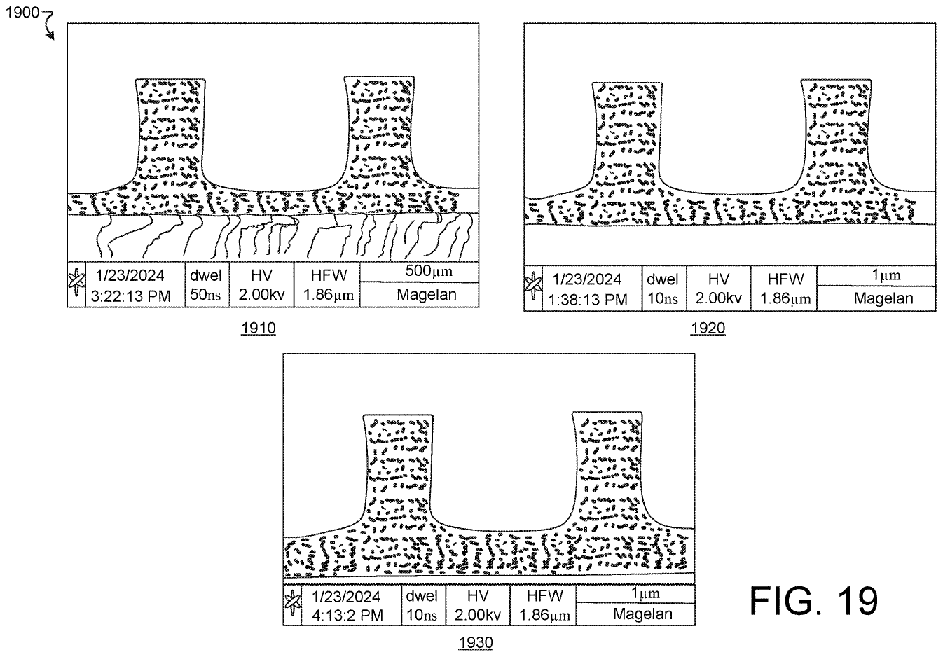

FIG. 18 is a diagram illustrating example plots 1800, 1830, and 1860 of the refractive index, film thickness, and film shrinkage of planar films utilizing a metal-oxo cluster (TiOC) as an inorganic binder at varying concentrations. Various types of inorganic binders can also be used. Metal-oxo clusters such as TiOC can be used to replace the silane coupling agent typically used for most of the imprinted structures described above. FIG. 18 shows the effects of using the metal-oxo cluster (TiOC) as the binder for TiO2 NPs in the formulation. Planar films on Si are prepared, calcined, and backfilled with TiO2 ALD and their film properties such as RI and film shrinkage are characterized at each fabrication step. At 1800, the RIs of the as-cured and calcined films decrease as the TiOC concentration increases in the formulation. During the ALD backfilling process, the degree of the RI increase is larger for higher TiOC concentrations, indicating some beneficial effects of using TiOC as a binder for the final achievable RI after ALD. The shrinkage of the films increases gradually as the TiOC concentration increases as shown in 1860.

FIG. 19 is a diagram illustrating example cross-sectional SEM images 1900 of as-imprinted binary grating patterns using varying concentrations (15% wt at 1910, 20% wt at 1920, 25% wt at 1930) of a metal-oxo cluster (TiOC) as an inorganic binder. FIG. 19 shows that the imprintability can remain almost the same in the presence of TiOC as the binder at least up to 30 wt % of TiOC in the formulation.

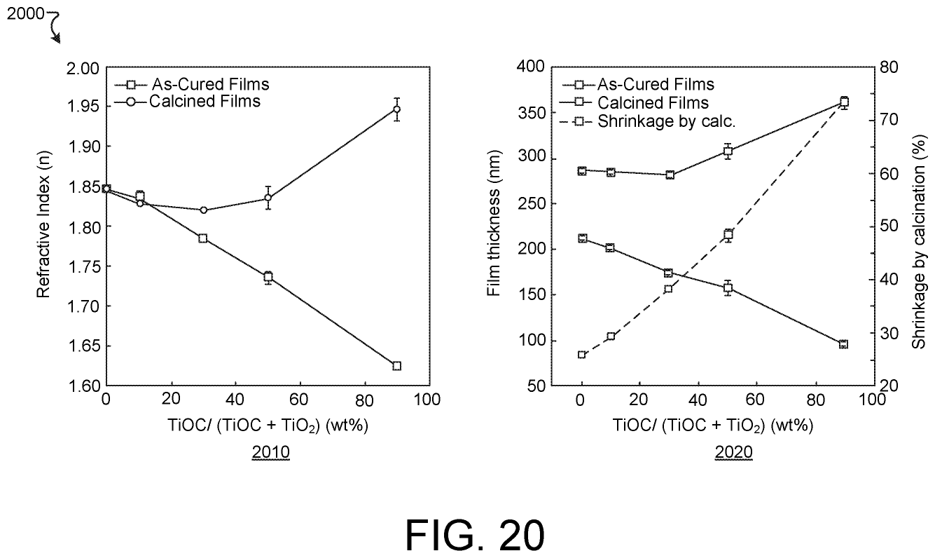

FIG. 20 is a diagram illustrating example plots 2000 of the film properties of planar films prepared using the metal-oxo cluster (TiOC) to partially replace TiO₂ nanoparticles. The metal-oxo cluster can also be used in replacement of TiO₂ NPs instead of being used as the binder. FIG. 20 shows the RI and thickness variation of the planar films before and after the calcination in terms of the weight ratio of TiOC relative to the total mass (TiOC+TiO₂ NPs). In At 2010, the RI of the as-cured films decreases as the TiOC ratio increases but that of the calcined films increases at higher TiOC ratios. At 2020, the shrinkage of the films by calcination gradually increases as the TiOC ratio increases.

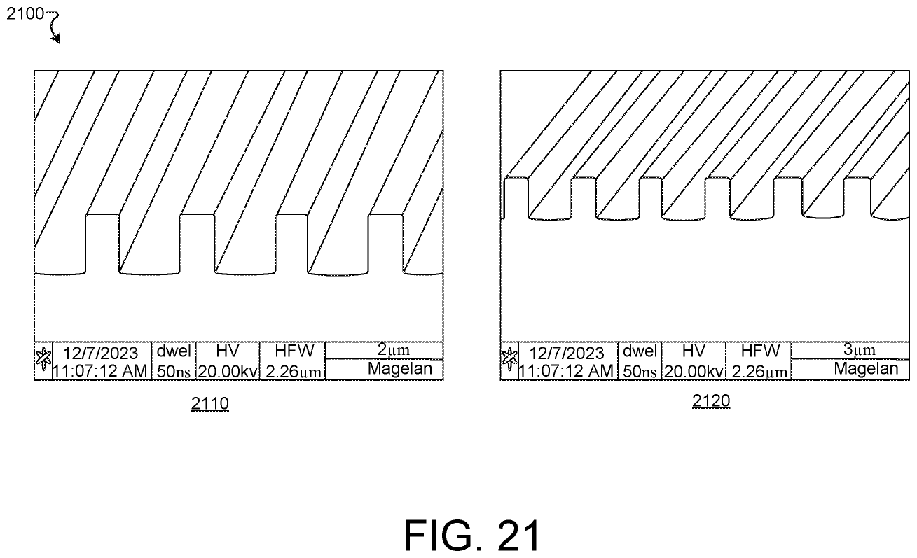

FIG. 21 is a diagram illustrating example cross-sectional SEM images 2100 of as-imprinted binary grating patterns where TiO₂ nanoparticles are replaced by TiOC at different weight ratios. FIG. 21 shows that the imprinted line patterns show high fidelity even though some of the nanoparticles are replaced by TiOC up to 50 wt %. At 2110, the weight ratio is 10% wt; at 2120, the weight ratio is 50% wt.

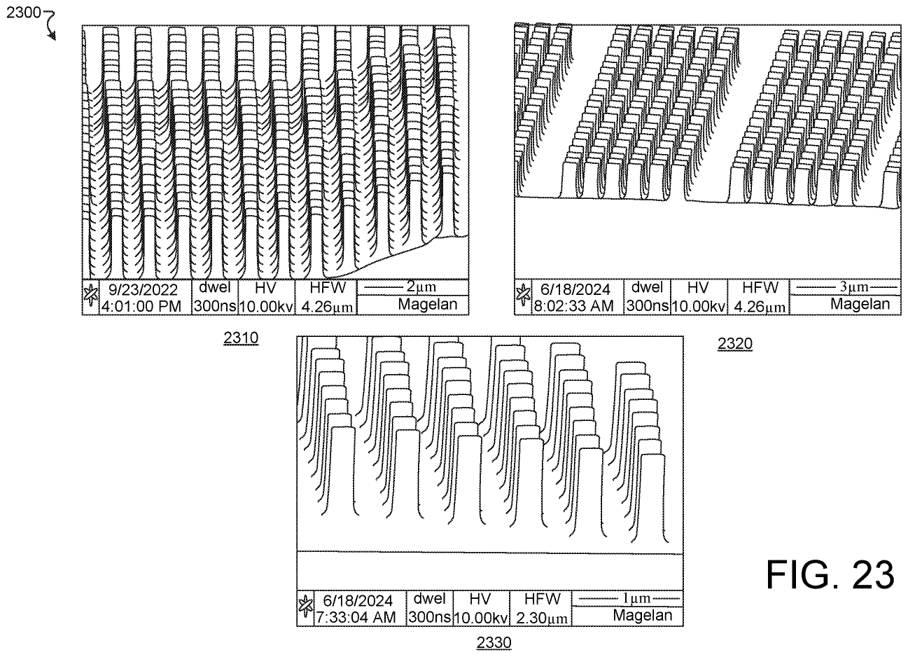

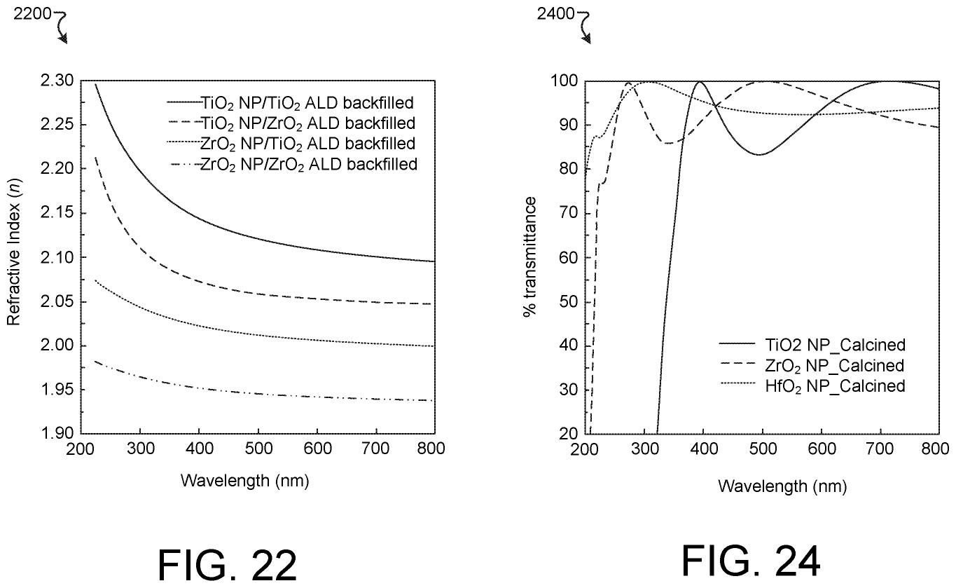

FIG. 22 is a diagram illustrating example plots 2200 of the refractive index demonstrating RI tunability by using different nanoparticles backfilled with different ALD precursors. ALD precursors can be the same or a different material as the base inorganic material of nanoparticles used for imprinting structures or mixtures of different ALD precursor materials. The ratio of the co-deposition of different ALD precursor materials can be tuned. A higher index ALD precursor can be used for the ALD backfill process to make a higher degree of RI change. FIG. 22 shows the tunability of RI by using a different nanoparticle and a different ALD precursor to backfill the porosity.

FIG. 23 is a diagram illustrating example SEM images 2300 of directly printed metalens structures prepared using BaTiO₃ (2310), ZrO₂ (2320), and HfO₂ (2330) nanoparticle-based inks. The selection of either TiO₂ or ZrO₂ nanoparticles together with the selection of either TiO₂ or ZrO₂ ALD precursors result in four different RIs. If these two particles can be mixed and two ALD precursors co-deposited, a finer tuning of RI can be feasible. Other nanoparticles and other ALD precursors can also be used. FIG. 23 shows the availability of various nanoparticles with good imprintability such as BaTiO₃ 2310, ZrO₂ 2320, and HfO₂ 2330, indicating that nanoparticles can be interchangeably used or mixed for various applications and wavelength targets.

FIG. 24 is a diagram illustrating example plots 2400 of the UV-vis spectra of ZrO₂ and HfO₂ nanoparticle-based films, showcasing their high transmittance in UV wavelength regimes. FIG. 24 illustrates that ZrO₂ and HfO₂ nanoparticle-based films are highly transparent to UV wavelength regimes which can be used as base materials for the fabrication of metasurface-based optical devices operating in UV wavelengths.

The process of ALD deposition can be tuned for high AR features with nanometer-sized pores. The use of an ALD process with a longer soaking of ALD precursors into the features and their pores is helpful to maximize the degree of the RI increase during the ALD backfill process. For example, the ALD precursors can be diffused into all the accessible features and inside pores by isolating the deposition chamber from the vacuum line during the diffusion step followed by removal of unreacted precursors and byproducts during the purging and vacuuming step.

Having larger 20 nm particles in the structures can increase the limit of the film thickness that the ALD precursor can uniformly diffuse by providing larger pore sizes and reducing the tortuosity of the diffusion path, whereas the thickness can be more limited when the smaller 10 nm NP is used alone whose smaller pore size provides more complex tortuosity. Tuning of the particle size and distribution enables control of the pore size and distribution which can be beneficial during the post-imprint ALD pore backfilling step.

Additional ALD depositions following the ALD backfill process on the imprinted, ALD-backfilled structures can be used to further change the feature dimensions and the RI. ALD precursors can be the same or a different material as the base inorganic material of nanoparticles used for imprinting structures or mixtures of different ALD precursor materials. The RI of the cladded ALD layer can be matched with the ALD-backfilled structure underneath or can be mismatched. Depending on the degree of RI mismatch between the backfilled layer and cladded layer, cladding a higher index ALD layer on the top of the imprinted structures can be helpful to yield higher device efficiency. Additional ALD depositions can also be used to smoothen the surface roughness of the imprinted structures.

ALD depositions can also be used to serve as a protective layer in case of device assembly between imprinted structures and other layers that can be disposed on it. For example, organic or polymeric layers can be deposited on the imprinted structures but protected by an additional ALD cladded layer (made of ALD precursors different from TiO₂) from the photocatalytic degradation by TiO₂ structures underneath.

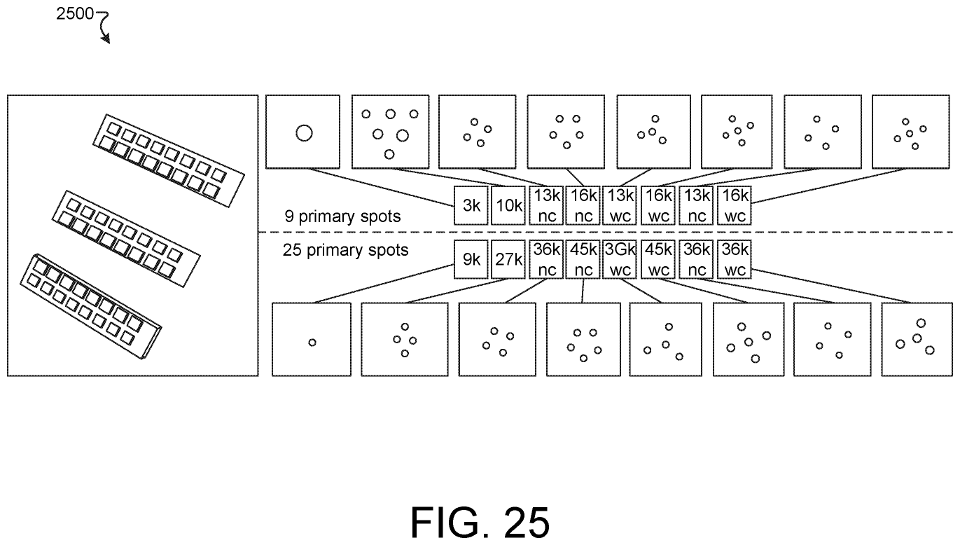

FIG. 25 is a diagram illustrating an example schematic description 2500 showing directly printed metasurface-based collimating beam splitters targeting thousands of dots when combined with a VCSEL array. As an example of the use of ALD post-processing to fabricate high-efficiency devices, metasurface-based collimating beam splitters can be patterned by direct NIL utilizing a blend of 10 nm and 20 nm TiO2 nanoparticles to achieve high RI and low shrinkage and can then be post processed with TiO2 ALD backfilling to reach the design RI of 2.20 at 940 nm. The beam splitting metasurfaces can be optically characterized with a fiber-coupled 940 nm laser to measure efficiencies, and they can also be combined with a vertical-cavity selective-emitting lasers (VCSEL) array to get an image contrast between the projected dots and the dark background. When combined with the VCSEL array, the 16 designs attain dot counts from 3,420 to 47,500.

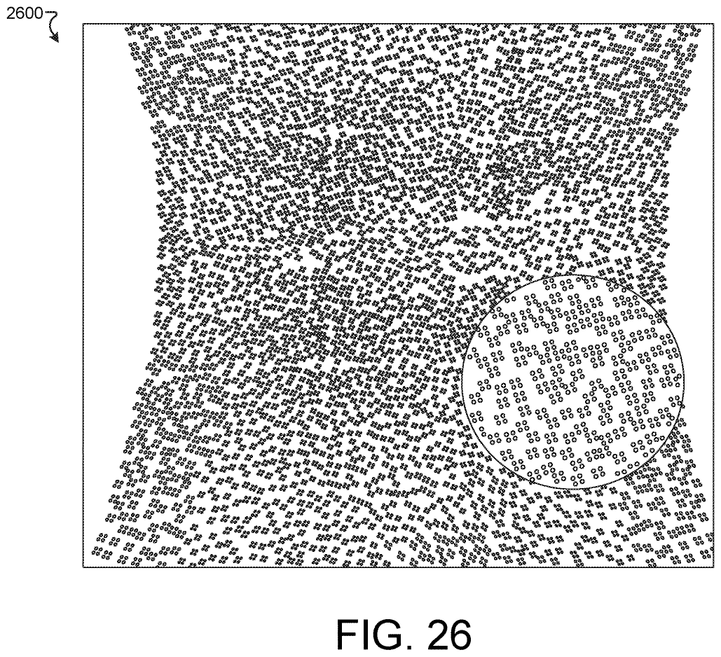

FIG. 26 is a diagram illustrating an example display 2600 of split dots on a dark screen at a distance of 30 cm utilizing a collimating beam splitter combined with a VCSEL array. FIG. 26 illustrates split dots on a dark screen at a distance of 30 cm using a collimating beam splitter combined with a 380 VCSEL array, showing an example of the 9 primary dots with the 4 secondary dot splitting.

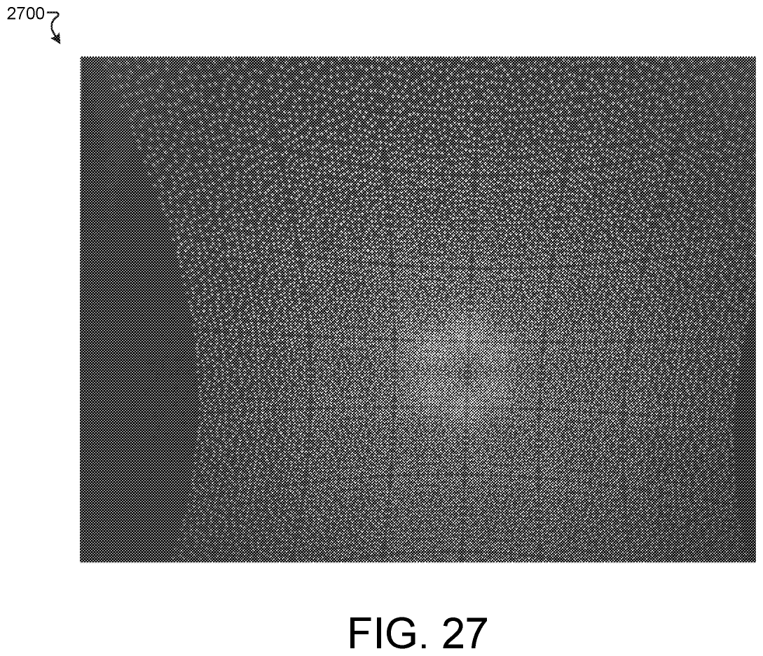

FIG. 27 is a diagram illustrating an example full screen image 2700 of a collimating beam splitter combined with a 380 VCSEL array at a distance of 30 cm showing dot counts of approximately 15,000 for a wider field of view. FIG. 27 shows another collimating beam splitter design with dot counts of 15,000 without dot splitting (42 primary dots) but more tiling for a wider FOV (7575°×83°). The average absolute dot efficiency is obtained up to 70% with a few dots'efficiency greater than 75%.

Paving a way to increase RIs offers additional freedom in designing other optical components involving waveguiding behavior because having higher RIs can be beneficial to meet the requirements for total internal reflection for reduced loss during propagation of in-coupled light. To avoid light scattering and power loss during light propagation, high optical density structures can be made with reduced surface roughness and grain size, e.g., at least 1/20 of the target wavelength. For patterned structures comprising nanoparticles, the control of particle size and surface roughness can increase the RI of the structures for high-performance optical devices.

Patterning of waveguiding structures composed of nanoparticles has been limited by low RI and high surface roughness, especially when nanoparticle-polymer composite materials are used for patterning. The RI of nanoparticle-based structures with polymeric binders has been limited to around 2.0. There may be ways to utilize phase transformation through thermal annealing of particles to a denser crystal phase to increase RIs but it entails increasing the grain size and surface roughness to a large extent, which can severely limit practical applications in optics due to the large grain size or the high surface roughness being greater than 1/20 of the target wavelength. As the RI for many materials decreases with increasing wavelength for transparent materials, patterning waveguiding structures in the IR regime gets more challenging due to lower RIs at higher wavelengths.

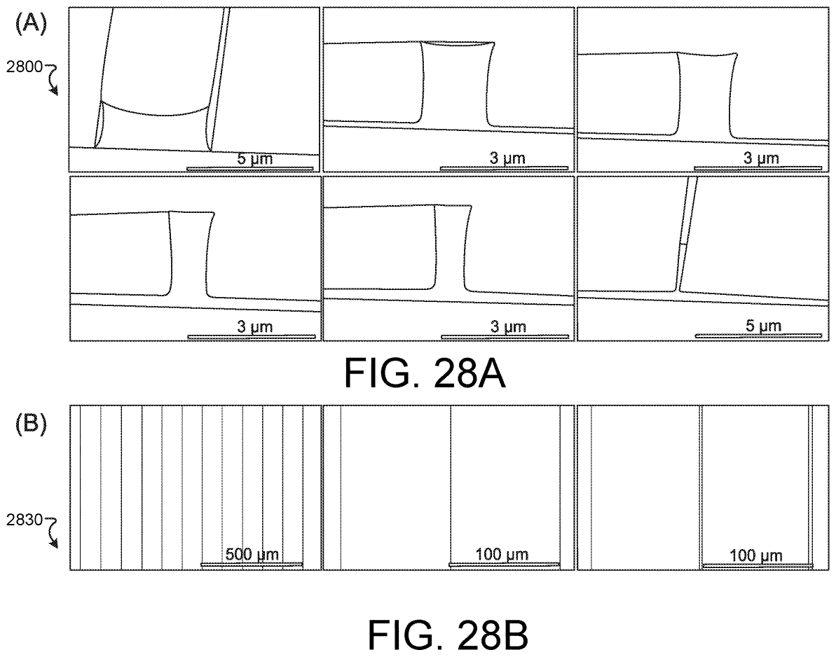

FIGS. 28A and 28B are diagrams illustrating example cross-sectional 2800 and top-down 2830 SEM images of line patterns fabricated with TiO₂ nanoparticle-based dispersions. FIGS. 28A and 28B illustrate an example of the patterned structures that can be used for waveguiding applications using the direct printing approach, showing a wide range of feature sizes and ARs. The patterned structures are straight line patterns and can function as a waveguiding structure in the visible and IR wavelength regimes. Patternable structures are not limited to the simple line pattern but can include more complicated structures such as slanted grating patterns, lines with curvature, lines with two-dimensional networks, etc. The images shown in FIGS. 28A and 28B demonstrate the coverage of a wide range of feature dimensions from 150 nm to 5 μm and aspect ratios from 0.5 to 10. The SEM images of the patterned structures show high feature fidelity and smooth surface.

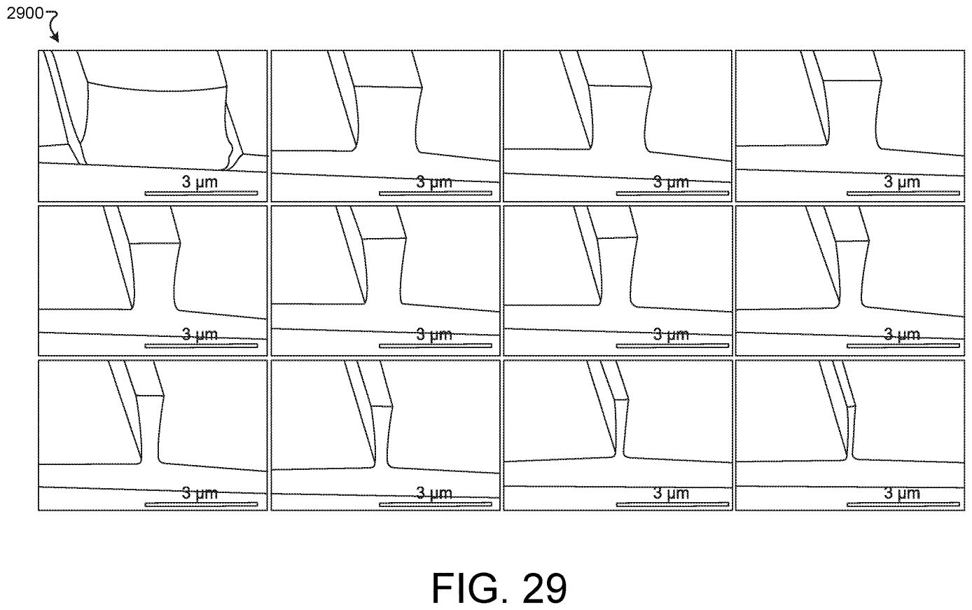

FIG. 29 is a diagram illustrating example cross-sectional SEM images 2900 of patterned line structures calcined at 450 °C in air. The calcination of the patterned structure in the air environment shown in FIG. 29 can remove any organic residues and make it an all-inorganic structure, which is then much more stable mechanically, thermally, and optically and is ideal for practical applications with long-term use in realistic environments and even in harsh environments that polymer composites would not be able to withstand. The organics remaining in the patterned structures can include ligands, binders, solvents, and any other materials or degraded byproducts of those materials that are present in nanoparticle dispersion formulations and not removed completely during the UV/thermal curing process. The calcination process can result in minor shrinkage of the patterned structures and can result in cracking primarily around the edges of large patterned features, represented by the largest feature in FIG. 29. Hence, depending on the target wavelength and application, there is a certain limit in terms of patternable structure dimensions with a given shrinkage value determined by the formulation used and calcination process used. The calcination temperature also affects the degree of shrinkage. Thus, the control of the calcination temperature is important. Further, annealing at high temperatures can also result in a change in crystal phases of nanoparticles. For example, the crystalline cores of TiO₂ nanoparticles undergo a temperature-dependent phase transformation from anatase to rutile at high temperatures starting around 600 °C or at a much higher temperature depending on the particle size compared to the transition temperature known for the bulk material. More importantly, this phase transformation to the denser crystalline phase can increase the RI. However, it should also be noted that this densification in turn means that grain size coarsening and surface roughening would take place at the same time.

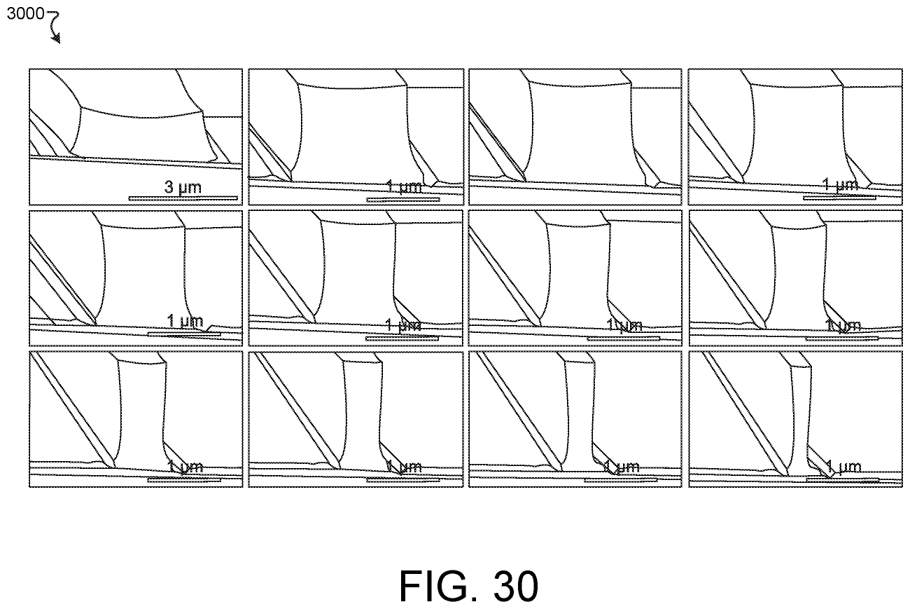

FIG. 30 is a diagram illustrating example cross-sectional SEM images 3000 of patterned line structures calcined at 1000 °C in air to show increased surface roughness. FIG. 30 shows the patterned line structures, calcined at a higher temperature of 1000 °C in air, present an increased surface roughness and a coarsened particle formation. Increasing the RI can be beneficial for optical applications but increasing grain size and surface roughness is detrimental in terms of light scattering. Thus, these two factors can be balanced considering the target wavelength, application and acceptable range of light scattering and power loss.

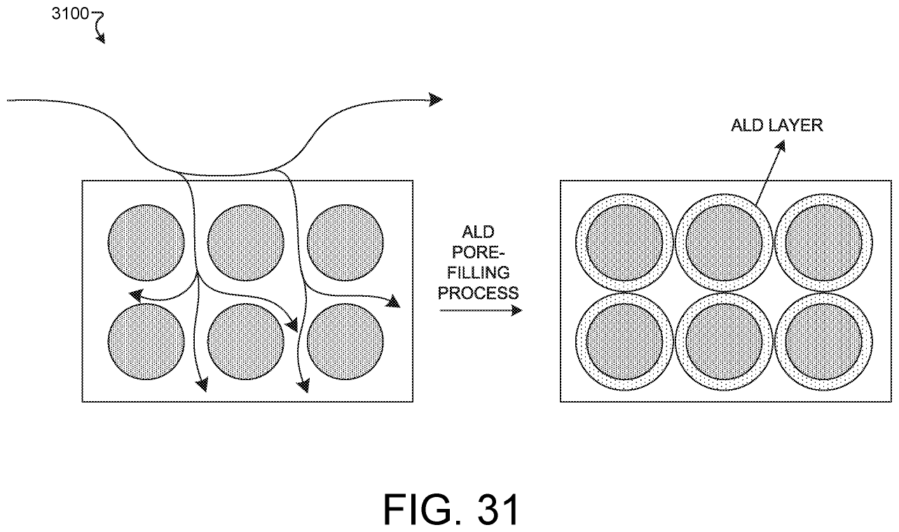

FIG. 31 is a diagram illustrating an example schematic description 3100 showing a process of pore filling between particles utilizing atomic layer deposition. Another way to increase the RI of NP-based structures is to increase the packing density of nanoparticles and other components comprising the dispersion ink for patterning as described above. Post-patterning processing is another efficient way to increase the RI further, in particularly through ALD. As schematically shown in FIG. 31, ALD can be utilized to fill in remaining porosity in the NP-based patterned structure. Because of very small pores formed and confined by densely packed nanoparticles, ALD is a suitable process to fill in the nanoscale porosity efficiently and uniformly due to the high diffusive nature of the gaseous precursor flow and its availability to form a self-limiting atomically thin layer in an angstrom scale. ALD can replace air voids and interstitial gaps between particles with high-index materials such as metal oxides. For example, the gaps between TiO2 nanoparticles can be filled with the same TiO₂ material, or with any other metal oxide precursors suitable for optical applications such as ZrO₂, HfO₂, Nb₂O₅, Al₂O₃ and SiO₂. Adjustments of ALD cycles and selections of precursor materials can enable fine tuning of the final RI and could provide a unique functionality by making a hybrid structured material through ALD.

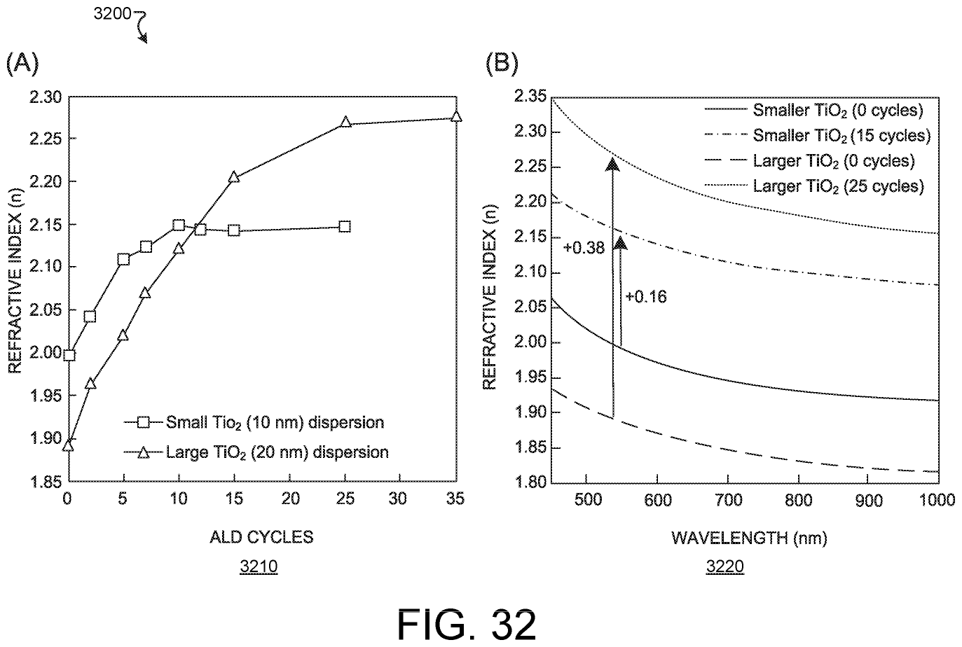

FIG. 32 is a diagram illustrating example plots 3200 of the refractive index of TiO₂ nanoparticle-based films in terms of ALD cycles and wavelength-dependent RI changes after full ALD backfilling. In addition to blending particles with different sizes, ALD post processing can further increase the RI to a larger extent just with a short ALD run. Since the average pore size is in the range of 2-3 nm for 10 nm and 20 nm TiO2 nanoparticles, backfilling this porosity uses a few tens of ALD cycles. Replacing air voids with high-index metal oxides such as TiO₂ by ALD changes the RI rapidly as described above. Further, the final RI can be tuned by controlling the number of ALD cycles. Plot 3210 shows the variation of the RI with ALD cycles of TiO₂ deposited onto two different films respectively composed of 10 nm and 20 nm TiO₂ NPs. It is shown that the RI is increased from 2.0 to 2.15 by >10 cycles for the 10 nm particle film while it is increased from 1.9 to 2.27 by >25 cycles. The levelling off of the RI graphs above a certain number of ALD cycles is due to the fact that once all the pores between nanoparticles are filled in by ALD, the rate of the RI increase slows down because ALD starts to form a thin cladding layer on top of the ALD-backfilled structures, which is relatively slow compared to the rate of the backfilling process due to the angstrom-scale growth rate of ALD. Plot 3220 compares the full RI graphs over a wide range of wavelengths before and after ALD backfilling process. The refractive index enhancement by a short ALD of 15-25 cycles is large. What can also be inferred from these graphs is that the extent of the RI increase by ALD backfilling is a function of the porosity or pore size defined by the primary nanoparticle size, 10 nm vs. 20 nm. This is based on the assumption that the material formed by ALD is usually denser than the material forming nanoparticles of the same kind. For example, 20 nm monodisperse particles can have a larger interstitial gap between particles than that formed by 10 nm monodisperse particles. This in turn means that having more accessible porosity or larger pores is another strategy to increase the ALD-driven RI enhancement as long as the patterned structures do not collapse or lose its structural integrity.

The RI of the final optical device can be controlled by the methods described so far acting alone or in combination. The methods include (1) tuning of formulations for maximum particle packing density, (2) post-processing of atomic layer deposition to fill in the remaining porosity, and (3) calcination at high temperatures to densify the structures further and to remove any residual organics, and (4) calcination to induce phase transformations to a denser crystalline structure. They can play all together and can affect one another. One thing to note in terms of the combinational effect of the methods is that an extent of phase transformation and the resulting grain size coarsening during the high temperature calcination can be controlled and suppressed by other methods in an earlier stage of process, for example, by modifying the formulation of nanoparticle dispersions and by changing materials used for ALD. That is, excessive crystal size growth or surface roughening can be properly restricted to a certain level at least some fabrication steps considering target wavelengths, applications, and acceptable ranges of light scattering and power loss.

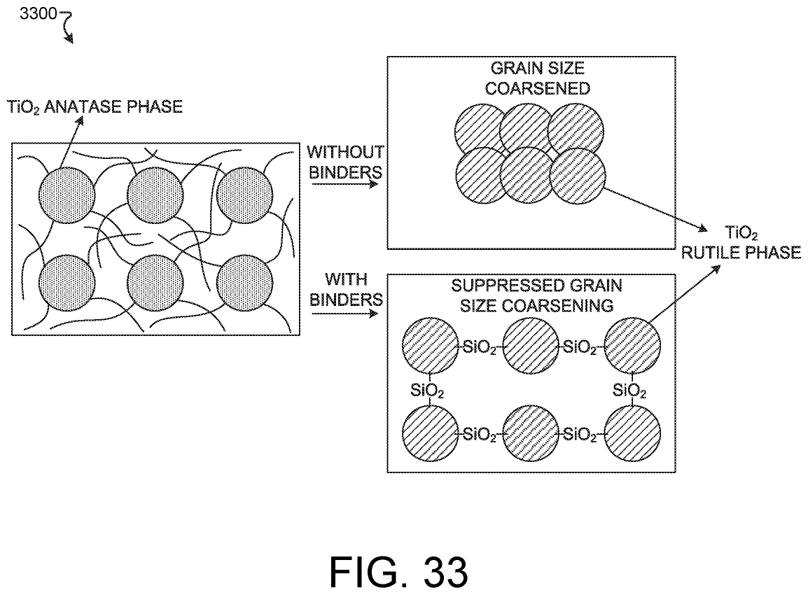

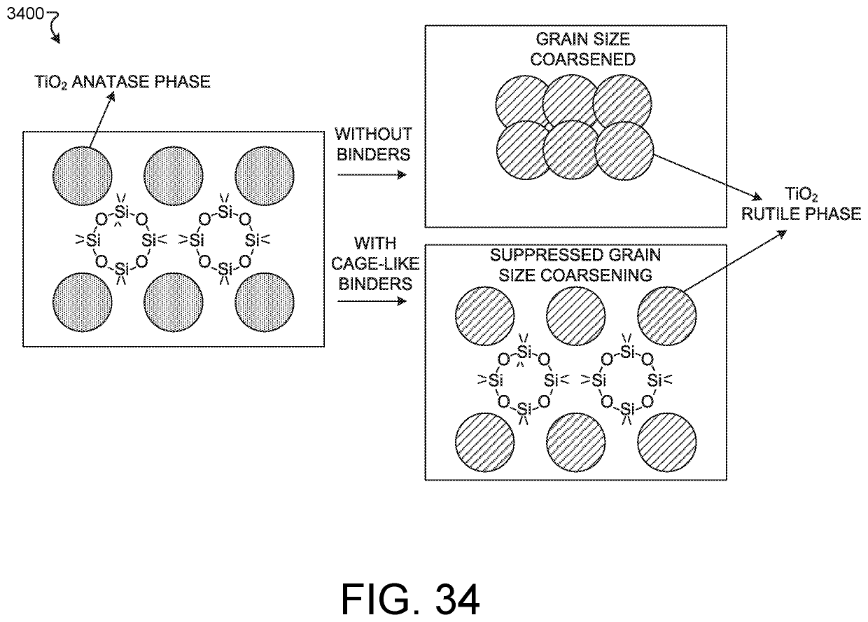

FIGS. 33-38 provide several examples of how to suppress excessive grain size coarsening and surface roughening. FIGS. 33-34 represent methods through the modification of binders connecting particles. Binders are added to nanoparticle dispersion inks to make patterned structures stronger in order to provide a wider range of patternable structures, especially useful for patterning of more complex structures such as high AR line patterns or slanted grating patterns. The latter require a mechanically stronger structure that can withstand the stamp release force exerted during the demolding process of the direct patterning method. Since binders are expected or designed to leave some chemical bonds between particles during the UV/thermal curing and during the calcination process, the remaining chemical bonds holding particles together in between can play a role.

FIG. 33 is a diagram illustrating an example schematic description 3300 showing the suppressing effects of binders on crystal phase transformation and grain size coarsening. As shown in FIG. 33 for example, particles undergo the phase transformation from anatase to rutile crystalline structures at a high temperature annealing process without any special binder, which accompanies grain size coarsening and surface roughening. In contrast, if a binder that can leave any inorganic bond such as SiO₂ that can survive calcination without changing phase, the SiO₂ bridges and linkages can act as a barrier, suppressing particle merging by recrystallization. Silane coupling agents possessing SiOₓ moieties can be an example to perform this role.

FIG. 34 is a diagram illustrating an example schematic description 3400 showing structural suppressing effects of binders via steric hindrance. Other binders leaving inorganic linkages that do not co-crystallize with the primary NPs are expected to do the same. FIG. 34 suggests a binder that can restrict particle coarsening and merging through physical separation of particles or steric hindrance. This example could include binders having a cage-like structure which is large enough to suppress direct physical contact points between particles thus restricting growth of the crystallite sizes by separating NPs with voids, minimizing contact sites. Metal-oxo clusters and silsesquioxanes are some examples expected to physically restrict the thermally driven particle fusing. In these examples, individual primary particles can still go through the phase transformation to a denser crystalline structure while the integration of adjacent particles is more limited or fully prevented.

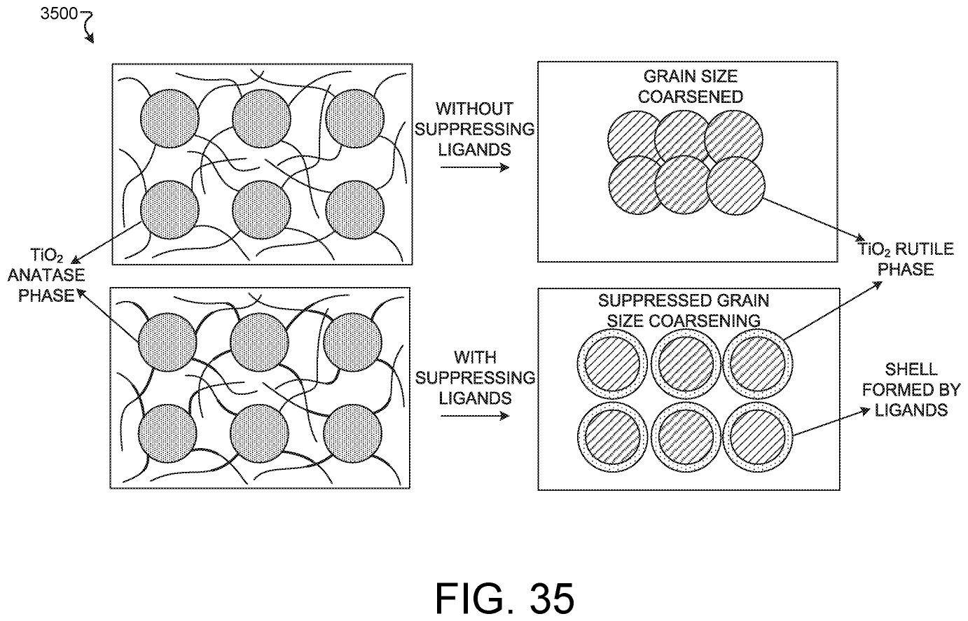

FIG. 35 is a diagram illustrating an example schematic description showing the suppressing effects of specialized ligands on crystal phase transformation and grain size coarsening. In a similar principle, the modification of ligand structures is another method as schematically described in FIG. 35. Particles can be properly covered with a specially designed ligand that can convert into an inorganic moiety covering individual particle and preventing it from particle coarsening. The modification can be achieved during the synthesis of the primary particles or through a ligand exchange reaction following the synthesis and during formulating a dispersion ink.

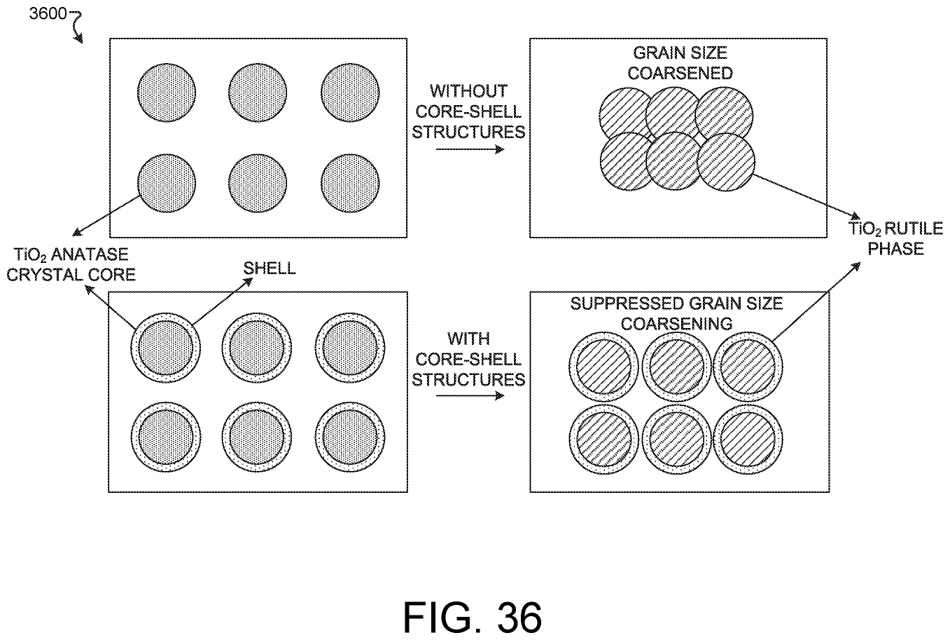

FIG. 36 is a diagram illustrating an example schematic description 3600 showing the suppressing effects of core-shell particles on crystal phase transformation. Redesign of particles is another feasible method to suppress excessive crystal growth as shown in FIG. 36. For example, a core-shell NP structure formed by two different inorganic materials that do not co-crystallize could protect itself from particle coarsening. Considering a change in particle shape of the core structure upon phase transformation, having a relatively softer shell or a shell loosely covering the core is a strategy to avoid rupturing the particle assembly during the phase transformation and densification.

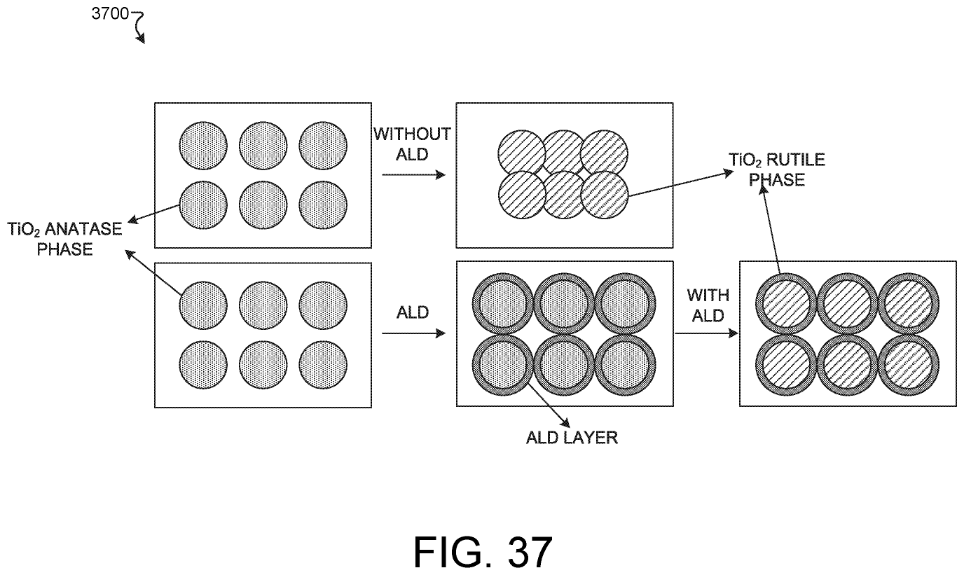

FIG. 37 is a diagram illustrating an example schematic description 3700 showing the suppressing effects of thin ALD layers placed between particles. A thin layer formed by ALD between particles can also suppress particle coarsening by choosing an appropriate material such as SiO₂ or Al₂O₃ prior to the thermal annealing process as shown in FIG. 37. The thin layers formed by ALD and placed between particles can also act as barriers preventing particle merging as long as the primary particles and ALD layers do not co-crystallize.

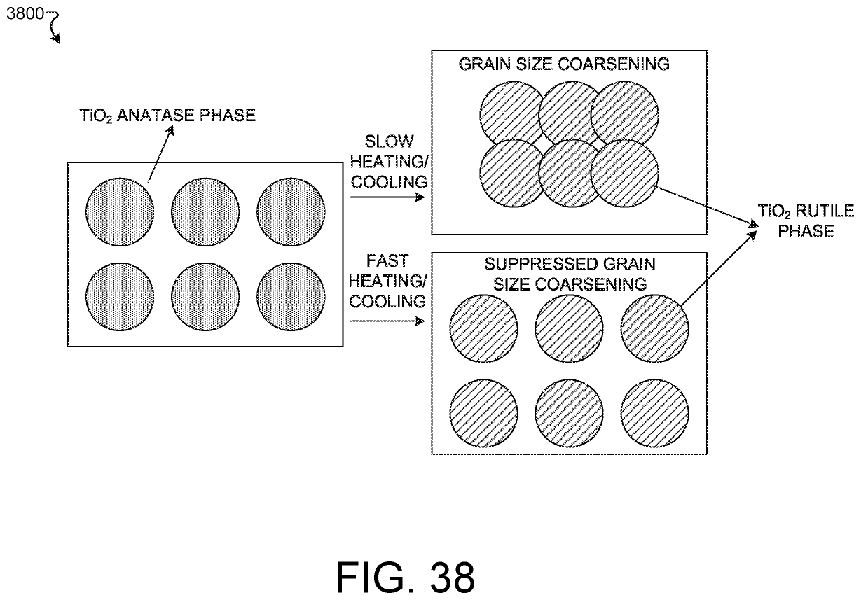

FIG. 38 is a diagram illustrating an example schematic description 3800 showing the effects of thermal cycling rates during rapid thermal annealing processes. The control of the heating and cooling rates of the thermal annealing process can result in a different extent of phase transformation and particle coarsening. As shown in FIG. 38, rapid thermal annealing (RTA) technique and process is known to heat up the chamber in seconds or in minutes to a very high temperature, which is different from hours of soaking in conventional tube furnaces giving enough time for particles to fully convert into a different crystalline phase and to merge with one another.

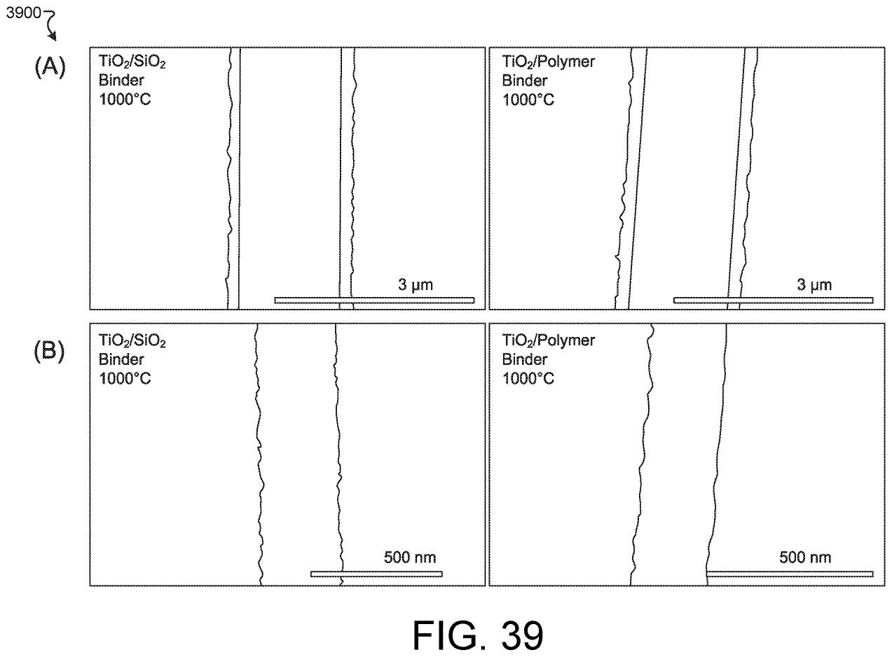

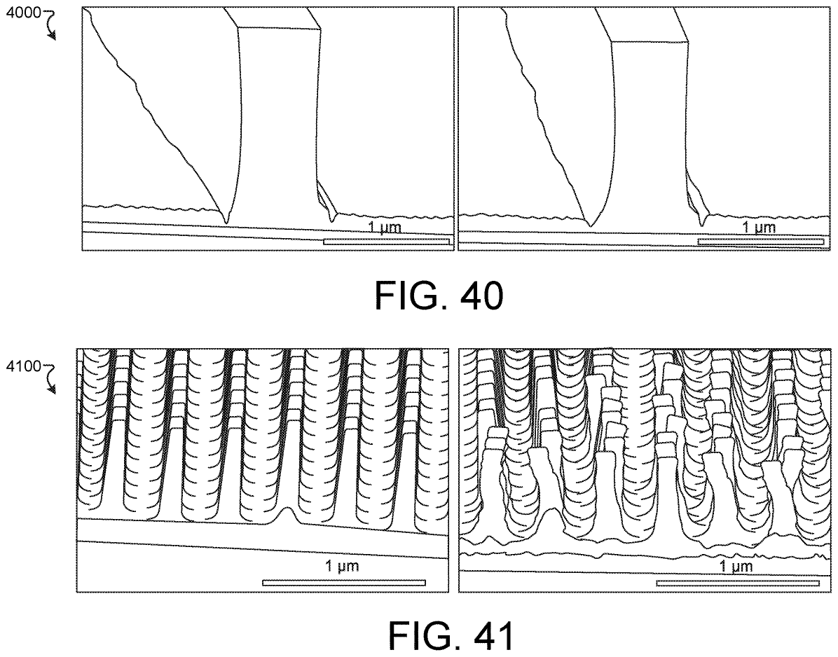

FIGS. 39 and 40 show the effects of using a different binder on grain size coarsening and surface roughening on patterned structures.

FIG. 39 is a diagram illustrating example top-down SEM images 3900 of line patterns comparing the effects of different binder types during the thermal annealing process. FIG. 39 compares top-down SEM images of line patterns fabricated with two different binder types, a silane couple agent leaving SiO2 linkages upon calcination and a polymeric binder (Norland Optical Adhesive; NOA) ashed upon calcination. TiO₂ NPs can more easily merge with adjacent particles upon the high temperature calcination at 1000 °C in air in the absence of any blocking binder in case of the polymeric binder, giving rise to a more coarsened particle structure and a rougher surface topography. In contrast, the SiO₂ binders between TiO₂ NPs suppressed the degree of particle coarsening and surface roughening.

FIG. 40 is a diagram illustrating example cross-sectional SEM images 4000 of line patterns comparing the effects of a silane coupling agent versus a polymeric binder after thermal annealing. FIG. 40 confirms the difference with cross-sectional SEM images.

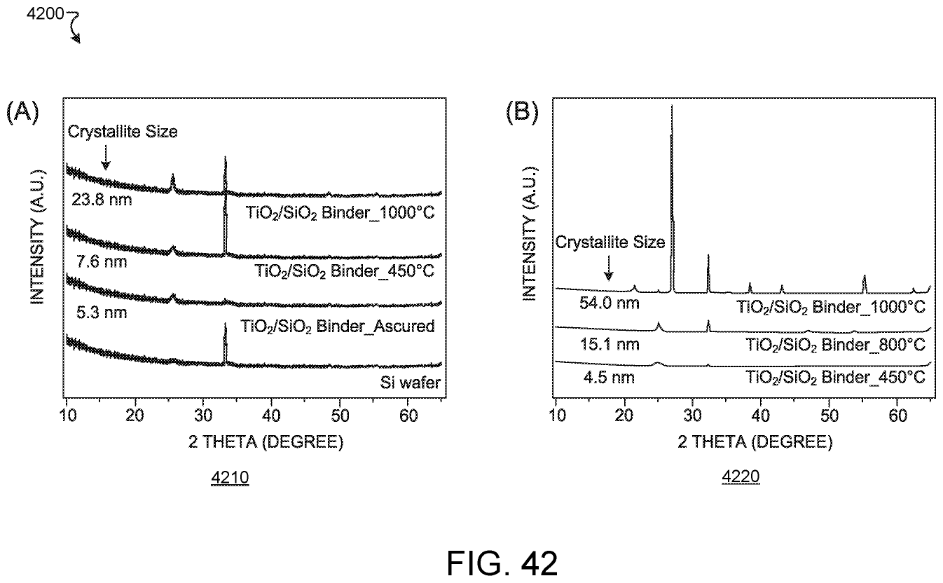

FIG. 41 is a diagram illustrating example cross-sectional SEM images 4100 of high aspect ratio nanopillars comparing the effects of binder types and the thermal annealing process. FIG. 41 shows another example of patterned structures exhibiting the difference. It is revealed that this particle coarsening effect without a proper binding system can also lead to the loss of structural integrity and the original shape of the patterned structure. The phase transformation into a different crystalline phase involving the shape change in crystalline structures can result in the shape change of patterned structures, which gets more obvious as ARs of the structures increase.

FIG. 42 is a diagram illustrating example wide-angle x-ray plots 4200 comparing planar films fabricated with a silane coupling agent in 4210 and a polymeric binder across annealing temperatures in 4220. Wide-angle X-ray diffraction results 4200 shown in FIG. 42 are in line with the SEM observations shown above. While 10 nm TiO₂ NPs (5 nm anatase crystalline core) with the polymeric binder convert from anatase to rutile phases and show an increase of average particle size up to 54 nm, those with the SiO₂ binder yields a negligible amount of the rutile phase at the same temperature and the average crystal size is smaller around 24 nm. This ascertains the suppression effect of grain size coarsening and surface roughening by incorporating a proper binder into nanoparticle-based dispersion inks used for patterning.

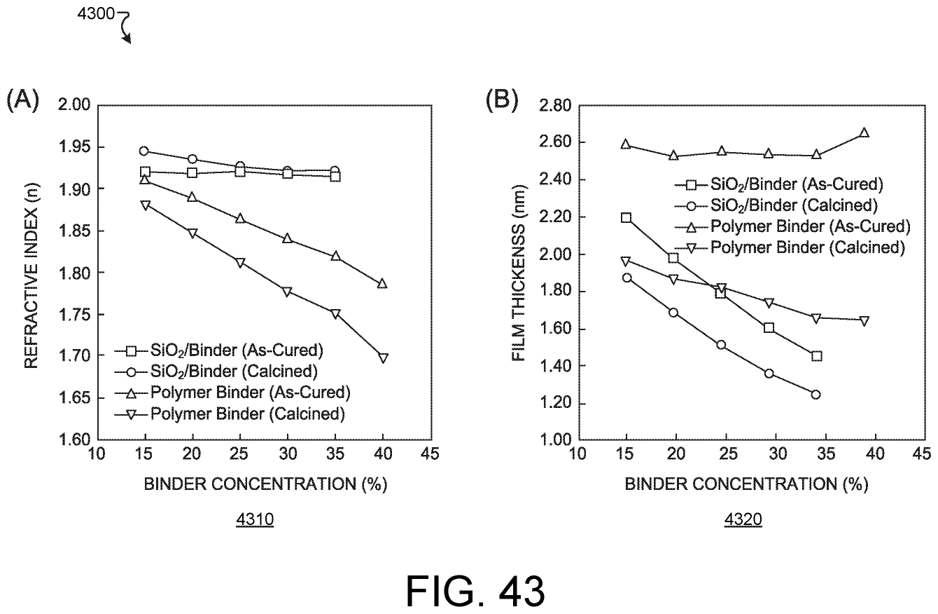

FIG. 43 is a diagram illustrating example plots 4300 of the refractive index in 4310 and film thickness in 4320 variations in relation to the binder concentration comparing two different binder types. The type and concentration of binders affects the porosity of NP-based structures. FIG. 43 compares the concentration effects of the two different binders in terms of RI. In case of the SiO₂ binder type, the increase of the binder concentration relative to the TiO₂ nanoparticle concentration shows a negligible effect on the refractive index of both as-cured films and calcined films at 450 °C. On the other hand, there is a decrease in RI values for the polymeric binder system, indicating an increase of porosity in the structures. Having a greater porosity reduces the RI at this stage of fabrication but it should be noted that ALD can be utilized to replace this porosity with a high-index metal oxide material. Thus, a porosity is possibly increased intentionally to backfill the porosity with ALD to reach a higher RI in the final stage of fabrication.

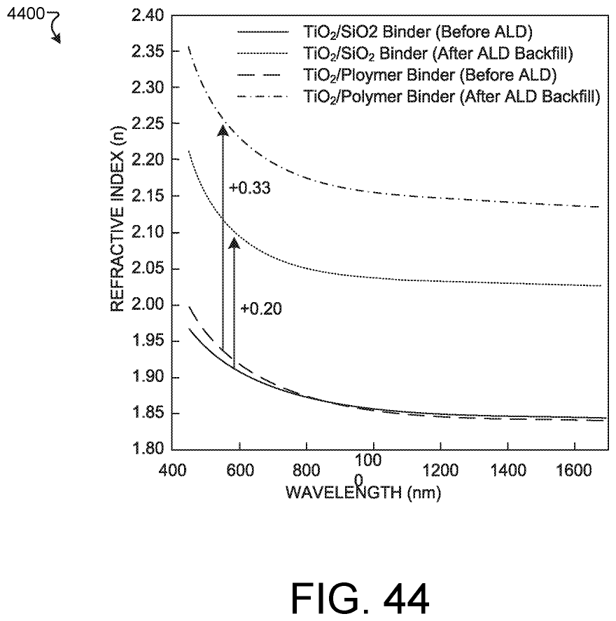

FIG. 44 is a diagram illustrating example plots 4400 of the wavelength-dependent refractive index curves comparing two different binder types before and after full ALD backfilling. As shown in FIG. 44, the starting RI of calcined films can be similar irrespective of binder types but in case of the polymeric binder acting as a porous template, a higher degree of RI enhancement is achieved by full backfilling of porosity by ALD.

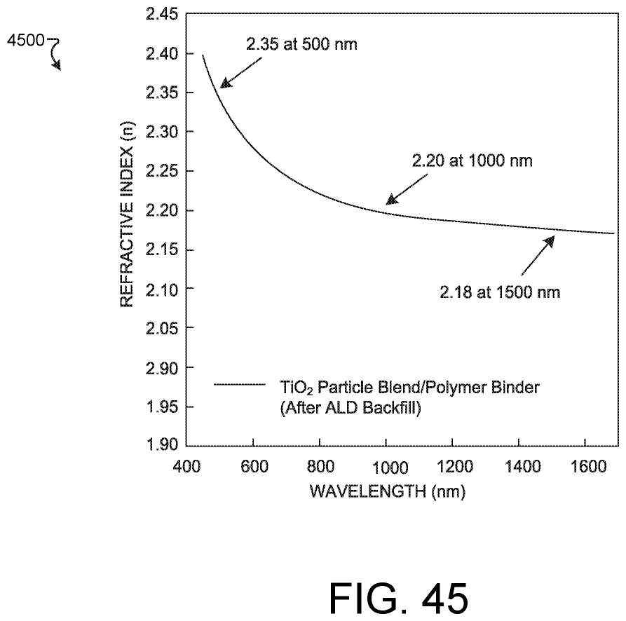

FIG. 45 is a diagram illustrating an example plot 4500 of the wavelength-dependent refractive index of a TiO₂ film utilizing a polymeric binder that is fully backfilled by TiO₂ ALD. FIG. 45 illustrates a combined effect of the methods described above including the particle blend increasing packing density, the porous template by polymeric binders, and porosity backfilling by ALD. Those three methods can increase the RI greatly up to 2.35 at 500 nm, 2.20 at 1000 nm, and 2.18 at 1500 nm.

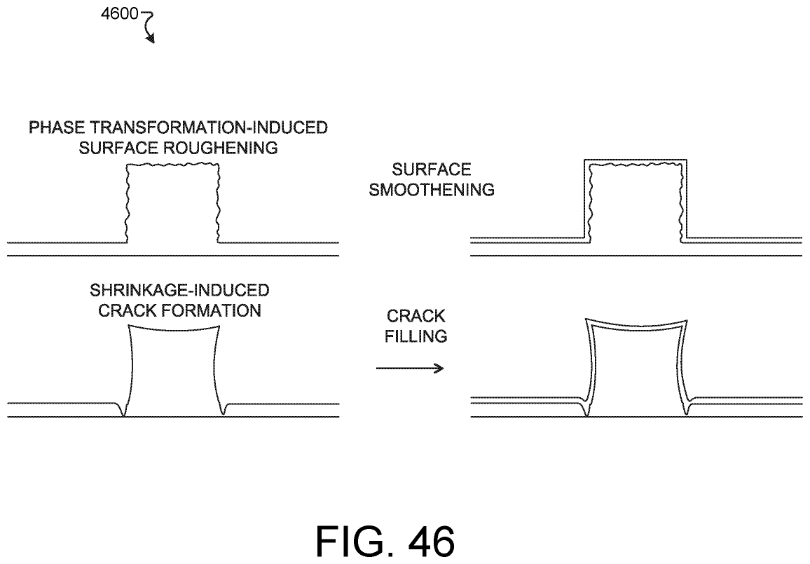

FIG. 46 is a diagram illustrating an example schematic description 4600 showing an ALD cladding process utilized to smoothen the surface roughness and fill in thermal cracks. ALD can be further utilized in addition to the backfilling process as schematically described in FIG. 46. Since some methods, particularly the high temperature annealing, involves grain size coarsening and surface roughening, forming a cladding layer using ALD is a way to mitigate such phenomena increasing light scattering. Due to the conformal coating nature of ALD, an additional ALD process following the pore-filling process enables smoothening of the roughened surface and filling in any cracks induced by thermal shrinkage, to the level of 1/20 of the target wavelength. A material for this cladding process can be different than the one used for the pore-filling process, can be designed to reduce a RI difference between the ALD-backfilled layer and the ALD-cladded layer, and can be a mixture for fine tuning of RI and surface property.

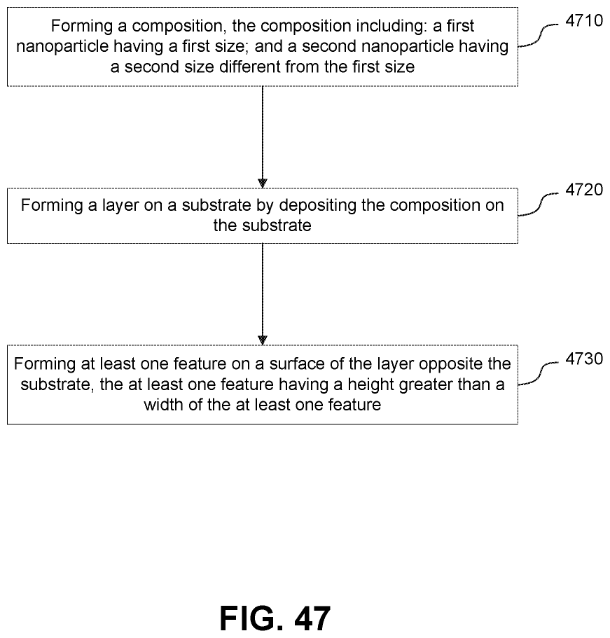

FIG. 47 is a flow chart illustrating an example process for additive manufacture of an advanced optical device.

At 4710, the method includes forming a composition, the composition including: a first nanoparticle having a first size; and a second nanoparticle having a second size different from the first size.

At 4720, the method includes forming a layer on a substrate by depositing the composition on the substrate.

At step 4730, the method includes forming at least one feature on a surface of the layer opposite the substrate, the at least one feature having a height greater than a width of the at least one feature.

Example 1. An optical device, comprising: a substrate; and a layer disposed on the substrate, the layer including a composition that includes: a first nanoparticle having a first size; a second nanoparticle having a second size different from the first size; and at least one feature on a surface of the layer opposite the substrate, the at least one feature being formed from the composition and having a height greater than a width of the at least one feature.

Example 2. The optical device of example 1, wherein the height of the at least one feature is at least ten times larger than the width of the at least one feature.

Example 3. The optical device of example 1, wherein the composition further includes: a first binder having a first size; and a second binder having a second size different from the first size.

Example 4. The optical device of example 3, wherein at least one of the first binder and the second binder includes one or more of a polymer, a monomer, an alkoxide, an oligomer, a prepolymer, an insulating material, a transparent optical adhesive, a silane, a metal oxide, a metal oxide precursor, a sol-gel material, a cross-linkable material, a Si-containing polymer, a caged polymer, a branched polymer, a silane coupling agent, a silsesquioxane, a metal-oxo cluster, or a combination thereof.

Example 5. The optical device of example 3, wherein at least one of the first nanoparticle and the second nanoparticle is in contact with at least one of the first binder and the second binder within the composition.

Example 6. The optical device of example 3, wherein the composition includes a plurality of pores.

Example 7. The optical device of example 6, wherein the plurality of pores is produced using a vapor phase.

Example 8. The optical device of example 3, wherein the first binder and the second binder are comprised of an inorganic material.

Example 9. The optical device of example 1, wherein the first nanoparticle and the second nanoparticle are comprised of an inorganic material.

Example 10. The optical device of example 1, wherein the composition is formed using atomic layer deposition of at least one precursor.

Example 11. The optical device of example 1, wherein the composition is treated to remove organic material.

Example 12. The optical device of example 1, wherein the layer is optically transparent in response to light of at least one wavelength incident on the layer.

Example 13. The optical device of example 1, wherein the first nanoparticle and the second nanoparticle include a metal oxide.

Example 14. The optical device of example 13, wherein the metal oxide includes titanium oxide.

Example 15. A method, comprising: forming a composition, the composition including: a first nanoparticle having a first size; and a second nanoparticle having a second size different from the first size; forming a layer on a substrate by depositing the composition on the substrate; and forming at least one feature on a surface of the layer opposite the substrate, the at least one feature having a height greater than a width of the at least one feature.

Example 16. The method of example 15, wherein forming the layer on the substrate includes: performing a spin-coat of the composition on the substrate.

Example 17. The method of example 15, wherein forming the at least one feature on the surface of the layer opposite the substrate includes: applying a patterned stamp to the surface of the layer opposite the substrate, the patterned stamp being configured to form the at least one feature on the surface via capillary action.

Example 18. The method of example 17, wherein forming the at least one feature on the surface of the layer opposite the substrate further includes: releasing the patterned stamp from the surface of the layer at a release angle that is based on a backing substrate of the patterned stamp.

Example 19. The method of example 17, wherein the patterned stamp is comprised of a hybrid polydimethylsiloxane (PDMS) material including a hard PDMS (hPDMS) material adjacent to the surface of the layer and a softer PDMS material disposed on the hPDMS material on a surface of the hPDMS material opposite the surface of the layer.

Example 20. The method of example 19, further comprising: adjusting a ratio of a thickness of the softer PDMS material to a thickness of the hPDMS material based on a pattern density of the at least one feature.

Example implementations can include a non-transitory computer-readable storage medium comprising instructions stored thereon that, when executed by at least one processor, are configured to cause a computing system to perform any of the methods described above. Example implementations can include an apparatus including means for performing any of the methods described above. Example implementations can include an apparatus including at least one processor and at least one memory including computer program code, the at least one memory and the computer program code configured to, with the at least one processor, cause the apparatus at least to perform any of the methods described above.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (a LED (light-emitting diode), or OLED (organic LED), or LCD (liquid crystal display) monitor/screen) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing system can include clients and servers. A client and server are generally remote from each other and typically interact through a communication network. The relationship of client and server arises by virtue of computer programs running on the respective computers and having a client-server relationship to each other.

A number of implementations have been described. Nevertheless, it will be understood that various modifications may be made without departing from the spirit and scope of the specification.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other implementations are within the scope of the following claims.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While example implementations may include various modifications and alternative forms, implementations thereof are shown by way of example in the drawings and will herein be described in detail. It should be understood, however, that there is no intent to limit example implementations to the particular forms disclosed, but on the contrary, example implementations are to cover all modifications, equivalents, and alternatives falling within the scope of the claims. Like numbers refer to like elements throughout the description of the figures.

Some of the above example implementations are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Methods discussed above, some of which are illustrated by the flow charts, may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a storage medium. A processor(s) may perform the necessary tasks.

Specific structural and functional details disclosed herein are merely representative for purposes of describing example implementations. Example implementations, however, may be embodied in many alternate forms and should not be construed as limited to only the implementations set forth herein.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example implementations. As used herein, the term and/or includes any and all combinations of one or more of the associated listed items.

It will be understood that when an element is referred to as being connected or coupled to another element, it can be directly connected or coupled to the other element or intervening elements may be present. In contrast, when an element is referred to as being directly connected or directly coupled to another element, there are no intervening elements present. Other words used to describe the relationship between elements should be interpreted in a like fashion (e.g., between versus directly between, adjacent versus directly adjacent, etc.).

The terminology used herein is for the purpose of describing particular implementations only and is not intended to be limiting of example implementations. As used herein, the singular forms a, an and the are intended to include the plural forms as well, unless the context clearly indicates otherwise. It will be further understood that the terms comprises, comprising, includes and/or including, when used herein, specify the presence of stated features, integers, steps, operations, elements and/or components, but do not preclude the presence or addition of one or more other features, integers, steps, operations, elements, components and/or groups thereof.

It should also be noted that in some alternative implementations, the functions/acts noted may occur out of the order noted in the figures. For example, two figures shown in succession may in fact be executed concurrently or may sometimes be executed in the reverse order, depending upon the functionality/acts involved.

Unless otherwise defined, all terms (including technical and scientific terms) used herein have the same meaning as commonly understood by one of ordinary skill in the art to which example implementations belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the above example implementations and corresponding detailed description are presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the above illustrative implementations, reference to acts and symbolic representations of operations (e.g., in the form of flowcharts) that may be implemented as program modules or functional processes include routines, programs, objects, components, data structures, etc., that perform particular tasks or implement particular abstract data types and may be described and/or implemented using existing hardware at existing structural elements. Such existing hardware may include one or more Central Processing Units (CPUs), digital signal processors (DSPs), application-specific-integrated-circuits, field programmable gate arrays (FPGAs) computers or the like.

It should be borne in mind, however, that all of these and similar terms are to be associated with the appropriate physical quantities and are merely convenient labels applied to these quantities. Unless specifically stated otherwise, or as is apparent from the discussion, terms such as processing or computing or calculating or determining or displaying or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Note also that the software implemented aspects of the example implementations are typically encoded on some form of non-transitory program storage medium or implemented over some type of transmission medium. The program storage medium may be magnetic (e.g., a floppy disk or a hard drive) or optical (e.g., a compact disk read only memory, or CD ROM), and may be read only or random access. Similarly, the transmission medium may be twisted wire pairs, coaxial cable, optical fiber, or some other suitable transmission medium known to the art. The example implementations are not limited by these aspects of any given implementation.

Lastly, it should also be noted that whilst the accompanying claims set out particular combinations of features described herein, the scope of the present disclosure is not limited to the particular combinations hereafter claimed, but instead extends to encompass any combination of features or implementations herein disclosed irrespective of whether or not that particular combination has been specifically enumerated in the accompanying claims at this time.

What is claimed is:

1. An optical device, comprising:
a substrate; and
a layer disposed on the substrate, the layer including a composition that includes:
a first nanoparticle having a first size;
a second nanoparticle having a second size different from the first size; and
at least one feature on a surface of the layer opposite the substrate, the at least one feature being formed from the composition and having a height greater than a width of the at least one feature.

2. The optical device of claim 1, wherein the height of the at least one feature is at least ten times larger than the width of the at least one feature.

3. The optical device of claim 1, wherein the composition further includes:
a first binder having a first size; and
a second binder having a second size different from the first size.

4. The optical device of claim 3, wherein at least one of the first binder and the second binder includes one or more of a polymer, a monomer, an alkoxide, an oligomer, a prepolymer, an insulating material, a transparent optical adhesive, a silane, a metal oxide, a metal oxide precursor, a sol-gel material, a cross-linkable material, a Si-containing polymer, a caged polymer, a branched polymer, a silane coupling agent, a silsesquioxane, a metal-oxo cluster, or a combination thereof.

5. The optical device of claim 3, wherein at least one of the first nanoparticle and the second nanoparticle is in contact with at least one of the first binder and the second binder within the composition.

6. The optical device of claim 3, wherein the composition includes a plurality of pores.

7. The optical device of claim 6, wherein the plurality of pores is produced using a vapor phase.

8. The optical device of claim 3, wherein the first binder and the second binder are comprised of an inorganic material.

9. The optical device of claim 1, wherein the first nanoparticle and the second nanoparticle are comprised of an inorganic material.

10. The optical device of claim 1, wherein the composition is formed using atomic layer deposition of at least one precursor.

11. The optical device of claim 1, wherein the composition is treated to remove organic material.

12. The optical device of claim 1, wherein the layer is optically transparent in response to light of at least one wavelength incident on the layer.

13. The optical device of claim 1, wherein the first nanoparticle and the second nanoparticle include a metal oxide.

14. The optical device of claim 13, wherein the metal oxide includes titanium oxide.

15. A method, comprising:
forming a composition, the composition including:
a first nanoparticle having a first size; and
a second nanoparticle having a second size different from the first size;
forming a layer on a substrate by depositing the composition on the substrate; and
forming at least one feature on a surface of the layer opposite the substrate, the at least one feature having a height greater than a width of the at least one feature.

16. The method of claim 15, wherein forming the layer on the substrate includes:
performing a spin-coat of the composition on the substrate.

17. The method of claim 15, wherein forming the at least one feature on the surface of the layer opposite the substrate includes:
applying a patterned stamp to the surface of the layer opposite the substrate, the patterned stamp being configured to form the at least one feature on the surface via capillary action.

18. The method of claim 17, wherein forming the at least one feature on the surface of the layer opposite the substrate further includes:
releasing the patterned stamp from the surface of the layer at a release angle that is based on a backing substrate of the patterned stamp.

19. The method of claim 17, wherein the patterned stamp is comprised of a hybrid polydimethylsiloxane (PDMS) material including a hard PDMS (hPDMS) material adjacent to the surface of the layer and a softer PDMS material disposed on the hPDMS material on a surface of the hPDMS material opposite the surface of the layer.

20. The method of claim 19, further comprising:
adjusting a ratio of a thickness of the softer PDMS material to a thickness of the hPDMS material based on a pattern density of the at least one feature.
